(19) United States
(12) Patent Application Publication
(10) Pub. No.: US 2024/0206297 A1
(43) Pub. Date: Jun. 20, 2024

(54) ELECTRONIC DEVICE COMPRISING DISPLAY

(71) Applicant: Samsung Electronics Co., Ltd., Suwon-si, Gyeonggi-do (KR)

(72) Inventors: Dongseop LEE, Suwon-si (KR); Junghyun KIM, Suwon-si (KR); Sungyoung SHIN, Suwon-si (KR); Byungduk YANG, Suwon-si (KR); Minsuk UHM, Suwon-si (KR); Yilin WU, Suwon-si (KR); Haechang LEE, Suwon-si (KR)

(21) Appl. No.: 18/417,602

(22) Filed: Jan. 19, 2024

Related U.S. Application Data
(63) Continuation of application No. PCT/KR2022/009001, filed on Jun. 24, 2022.

(30) Foreign Application Priority Data
Aug. 13, 2021 (KR) 10-2021-0107495

(51) Int. Cl. H10K 59/80; G06F 3/044; H10K 59/122; H10K 59/35; H10K 59/38; H10K 59/40

(52) U.S. Cl. CPC H10K 59/8792; G06F 3/0446; H10K 59/122; H10K 59/353; H10K 59/38; H10K 59/40

(57) ABSTRACT

An electronic device is provided. The electronic device includes a board, a plurality of pixels including a first pixel disposed on the board, and including a first organic light emitting layer including a first sub-organic light emitting layer and a second sub-organic light emitting layer, and a second pixel including a second organic light emitting layer, a pixel definition layer located between the first sub-organic light emitting layer and the second sub-organic light emitting layer, a first light shielding member located on the pixel definition layer to overlap the pixel definition layer between the first and second sub-organic light emitting layer in a first direction, and an opaque member overlapping the first light shielding member in the first direction, and located between at least a portion of the pixel definition layer located between the first sub-organic light emitting layer and the second sub-organic light emitting layer, and the first light shielding member.

### CROSS-REFERENCE TO RELATED APPLICATION(S)

This application is a continuation application, claiming priority under § 365(c), of an International application No. PCT/KR2022/009001, filed on Jun. 24, 2022, which is based on and claims the benefit of a Korean patent application number 10-2021-0107495, filed on Aug. 13, 2021, in the Korean Intellectual Property Office, the disclosure of which is incorporated by reference herein in its entirety.

### BACKGROUND

### 1. Field

The disclosure relates to an electronic device including a display. More particularly, the disclosure relates to an electronic device that effectively restrict an angle of view of a screen according to selection of a user by preventing light leakage due to light that travels at a low angle.

### 2. Description of Related Art

Electronic devices, including smartphones, tablet process control system (PCs), and wearable devices, which have various functions, have been continuously distributed more and more. Such an electronic device may include a display for outputting visual information. The display may display a screen by using a plurality of pixels. When a user uses an electronic device, the screen of the electronic device may be easily recognized by persons around the user, as well as by the user. As a result, regardless of an intention of the user, information that is not intended to be revealed may be exposed to another person.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device, by which a user selectively adjust an angle of view of a screen.

Another aspect of the disclosure is to provide an electronic device that effectively restrict an angle of view of a screen according to selection of a user by preventing light leakage due to light that travels at a low angle.

Additional aspects will be set forth in part in the description which follows and, in part, will be apparent from the description, or may be learned by practice of the presented embodiments.

In accordance with an aspect of the disclosure, an electronic device is provided. The electronic device includes a board, a plurality of pixels including a first pixel disposed on the board, and including a first organic light emitting layer including a first sub-organic light emitting layer and a second sub-organic light emitting layer, which are spaced apart from each other, and a second pixel including a second organic light emitting layer, a pixel definition layer located between the first sub-organic light emitting layer and the second sub-organic light emitting layer, a first light shielding member located on the pixel definition layer to overlap the pixel definition layer between the first sub-organic light emitting layer and the second sub-organic light emitting layer in a first direction, and an opaque member overlapping the first light shielding member in the first direction, and located between at least a portion of the pixel definition layer located between the first sub-organic light emitting layer and the second sub-organic light emitting layer, and the first light shielding member.

In accordance with another aspect of the disclosure, an electronic device according to an embodiment of the disclosure is provided. The electronic device includes a display, and the display may include a first pixel including at least two light emitting areas that are driven based on the same data voltage and the same gate signal and are spaced apart from each other, a first light shielding member including a plurality of openings located on the first pixel to surround the light emitting areas of the first pixel and aligned with the light emitting areas of the first pixel, and an opaque member overlapping the first light shielding member in a first direction.

According to embodiments disclosed in the disclosure, a user selectively adjust an angle of view of a screen of an electronic device.

Furthermore, according to embodiments disclosed in the disclosure, an angle of view of a screen be effectively restricted according to selection of a user by preventing light leakage due to light that travels at a low angle.

In addition, the disclosure provides various effects that are directly or indirectly recognized.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment, according to an embodiment of the disclosure;

FIG. 2 is a block diagram of a display module according to an embodiment of the disclosure;

FIG. 3 is a view illustrating a plurality of pixels included in a display according to an embodiment of the disclosure;

FIG. 4 is a view illustrating some configurations included in a display according to an embodiment of the disclosure;

FIG. 5 is a schematic plan view of a touch sensing layer included in a display according to an embodiment of the disclosure;

FIG. 6 is a plan view illustrating a first touch pattern layer of area “A” of FIG. 5 according to an embodiment of the disclosure;

FIG. 7 is an enlarged view illustrating area “B” of FIG. 6 according to an embodiment of the disclosure;

FIG. 8 is a plan view illustrating a second touch pattern layer of area “A” of FIG. 5 according to an embodiment of the disclosure;

FIG. 9 is an enlarged view illustrating area “C” of FIG. 8 according to an embodiment of the disclosure;

FIG. 10 is a cross-sectional view of an area of a display included in an electronic device according to an embodiment of the disclosure;

FIG. 11 is a cross-sectional view of an area of a display included in an electronic device according to an embodiment of the disclosure;

FIG. 12 is a cross-sectional view of an area of a display included in an electronic device according to an embodiment of the disclosure;

FIG. 13 is a cross-sectional view of an area of a display included in an electronic device according to an embodiment of the disclosure;

FIG. 14 is a cross-sectional view of an area of a display included in an electronic device according to an embodiment of the disclosure;

FIG. 15 is a cross-sectional view of an area of a display included in an electronic device according to an embodiment of the disclosure;

FIG. 16 is a cross-sectional view of an area of a display included in an electronic device according to an embodiment of the disclosure; and

FIG. 17 is a cross-sectional view of an area of a display included in an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modification of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory or the one or more computer programs may be divided with different portions stored in different multiple memories.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

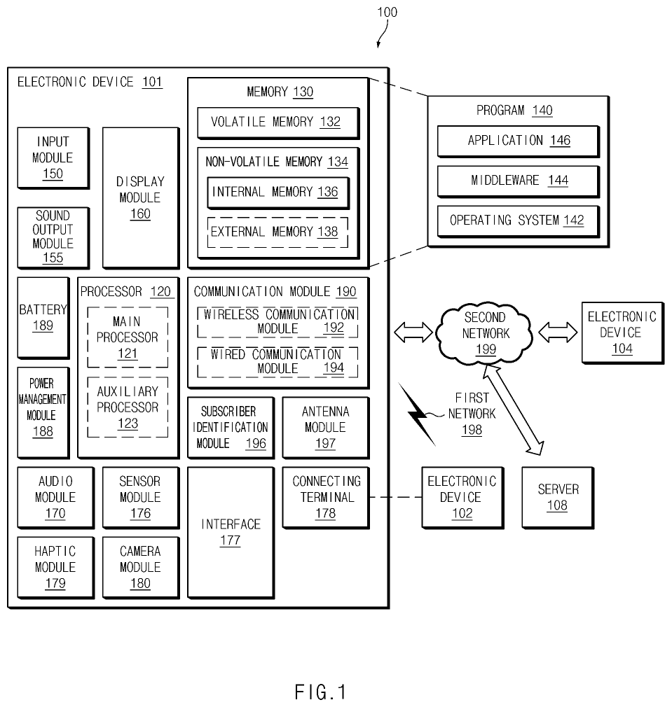

FIG. 1 is a block diagram illustrating an electronic device in a network environment according to an embodiment of the disclosure.

Referring to FIG. 1, an electronic device 101 in a network environment 100 may communicate with an external electronic device 102 via a first network 198 (e.g., a short-range wireless communication network), or an external electronic device 104 or a server 108 via a second network 199 (e.g., a long-range wireless communication network). According to an embodiment of the disclosure, the electronic device 101 may communicate with the external electronic device 104 via the server 108. According to an embodiment of the disclosure, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments of the disclosure, at least one (e.g., the connecting terminal 178) of the components may be omitted from the electronic device 101, or one or more other components may be added in the electronic device 101. In some embodiments of the disclosure, some of the components may be implemented as single integrated circuitry. For example, some (e.g., the sensor module 176, the camera module 180, or the antenna module 197) of the components may be implemented as embedded in the display module 160 (e.g., a display).

The processor 120 may execute, for example, software (e.g., a program 140) to control at least one other component (e.g., a hardware or software component) of the electronic device 101 coupled with the processor 120, and may perform various data processing or computation. According to one embodiment of the disclosure, as at least part of the data processing or computation, the processor 120 may load a command or data received from another component (e.g., the sensor module 176 or the communication module 190) in volatile memory 132, process the command or the data stored in the volatile memory 132, and store resulting data in non-volatile memory 134. According to an embodiment of the disclosure, the processor 120 may include a main processor 121 (e.g., a central processing unit (CPU) or an application processor (AP)), and an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. When the electronic device 101 includes the main processor 121 and the auxiliary processor, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an embodiment of the disclosure, the auxiliary processor 123 (e.g., an image signal processor or a communication processor) may be implemented as part of another component (e.g., the camera module 180 or the communication module 190) functionally related to the auxiliary processor 123. According to an embodiment of the disclosure, the auxiliary processor 123 (e.g., a neural network processing device) may include a hardware structure specified for processing an artificial intelligence (AI) model. The AI model may be generated through machine learning. The learning may be performed by the electronic device 101 performing the AI, and may be performed through an additional server (e.g., the server 108). A learning algorithm may include, for example, a supervised learning algorithm, an unsupervised learning algorithm, a semi-supervised learning algorithm, or a reinforcement learning algorithm, but the disclosure is not limited thereto. The AI model may include a plurality of artificial neural network (ANN) layers. The ANN may include a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-networks or the combination of the above networks, but the disclosure is not limited thereto. The AI model may additionally or alternatively include a software structure, in addition to a hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record, and the receiver may be used for an incoming calls. According to an embodiment of the disclosure, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment of the disclosure, the display module 160 may include touch sensor adapted to detect a touch, or a pressure sensor adapted to measure the intensity of force incurred by the touch.

The audio module 170 may convert a sound into an electrical signal and vice versa. According to an embodiment of the disclosure, the audio module 170 may obtain the sound via the input module 150, or output the sound via the sound output module 155 or an external electronic device (e.g., the external electronic device 102) (e.g., speaker of headphone) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment of the disclosure, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment of the disclosure, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the external electronic device 102). According to an embodiment of the disclosure, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment of the disclosure, the haptic module 179 may include, for example, a motor, a piezoelectric element, or an electric stimulator.

The camera module 180 may capture a still image or moving images. According to an embodiment of the disclosure, the camera module 180 may include one or more lenses, image sensors, image signal processors, or flashes.

The power management module 188 may manage power supplied to the electronic device 101. According to one embodiment of the disclosure, the power management module 188 may be implemented as at least part of, for example, a power management integrated circuit (PMIC).

The battery 189 may supply power to at least one component of the electronic device 101. According to an embodiment of the disclosure, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment of the disclosure, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). The corresponding communication module from among the communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, fifth generation (5G) network, next generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network and a next-generation communication technology, for example, a new radio (NR) access technology after a fourth generation (4G) network. The NR access technology may support high-speed transmission for high capacity data (enhanced mobile broadband; eMBB), terminal power minimizing and multiple terminal access (massive machine type communication; mMTC), or ultra-reliable and low-latency communications (URLLC). The wireless communication module 192 may support a high-frequency band (e.g., millimeter wave (mmWave) band) to achieve, for example, a higher data rate. The wireless communication module 192 may support various technologies, for example, beamforming, massive multiple-input and multiple-output (MIMO), Full-dimensional MIMO, an array antenna, analog beam-forming, or a large-scale antenna, to secure performance in high frequency bands. The wireless communication module 192 may support various requirements defined in the electronic device 101, the external electronic device (e.g., the external electronic device 104) or the network system (e.g., the second network 199). According to one embodiment of the disclosure, the wireless communication module 192 may support a peak data rate (e.g., 20 gigabits per second (Gbps) or more) for eMBB realization, loss coverage (e.g., 164 decibels (dB) or less) for mMTC realization, or U-plane latency (e.g., 0.5 milliseconds (ms) or less, or the round trip of 1 ms or less in each of a downlink (DL) and an uplink (UL)) for URLCC realization.

The antenna module 197 may transmit or receive a signal or power to or from the outside (e.g., the external electronic device) of the electronic device 101. According to an embodiment of the disclosure, the antenna module 197 may include an antenna including a radiating element including a conductive material or a conductive pattern formed in or on a substrate (e.g., printed circuit board (PCB)). According to an embodiment of the disclosure, the antenna module 197 may include a plurality of antennas (e.g., an array antenna). In such a case, at least one antenna appropriate for a communication scheme used in the communication network, such as the first network 198 or the second network 199, may be selected, for example, by the communication module 190 from the plurality of antennas. The signal or the power may then be transmitted or received between the communication module 190 and the external electronic device via the selected at least one antenna. According to an embodiment of the disclosure, another component (e.g., a radio frequency integrated circuit (RFIC)) other than the radiating element may be additionally formed as part of the antenna module 197.

According to various embodiments of the disclosure, the antenna module 197 may form an mmWave antenna module. According to an embodiment of the disclosure, the mmWave antenna module may include a printed circuit board, an RFIC disposed on a first surface (e.g., a bottom surface) of the printed circuit board, or disposed adjacent to the first surface to support the specific high frequency band (e.g., mmWave band), and a plurality of antennas (e.g., an array antenna) disposed on a second surface (e.g., a top surface or a side surface) of the printed circuit board or disposed adjacent to the second surface to transmit or receive a signal having the specified high frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment of the disclosure, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment of the disclosure, all or some of operations to be executed at the electronic device 101 may be executed at one or more of the external electronic devices 102, 104, or 108. For example, when the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide an ultra-latency service by using, for example, distributed computing or mobile edge computing. According to various embodiments of the disclosure, the external electronic device 104 may include the Internet of things (IoT). The server 108 may be an artificial server using machine learning and/or a neural network. According to an embodiment of the disclosure, the external electronic device 104 or the server 108 may be included in the second network 199. The electronic device 101 may be applied to an artificial intelligence service (e.g., a smart home, a smart city, a smart car, or healthcare service) based on the 5G communication technology and the IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1^{st}” and “2^{nd},” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment of the disclosure, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities and some of multiple entities may be separately disposed on the other components. According to various embodiments of the disclosure, one or more of the above-described components may be omitted, or one or more other components may be added. Alternatively or additionally, a plurality of components (e.g., modules or programs) may be integrated into a single component. In such a case, according to various embodiments of the disclosure, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

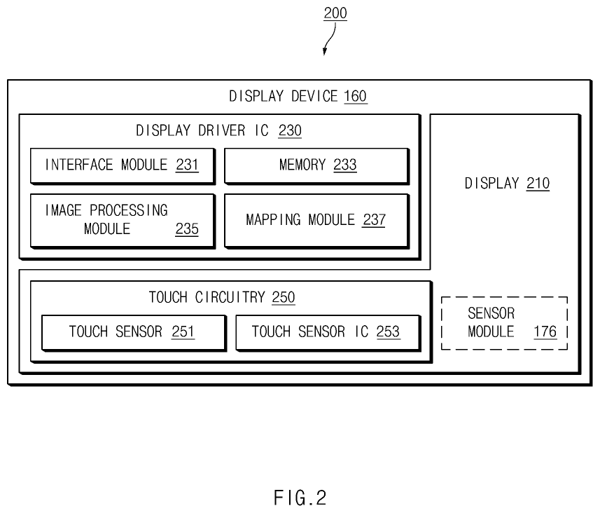

FIG. 2 is a block diagram 200 of a display module according to an embodiment of the disclosure.

Referring to FIG. 2, the display module 160 may include a display 210 and a display deriver integrated circuit (DDIC) 230 to control the display 210. The DDIC 230 may include an interface module 231, memory 233 (e.g., buffer memory), an image processing module 235, or a mapping module 237. The DDIC 230 may receive image information including, for example, image data or an image control signal corresponding to a command for controlling image data, from another component of the electronic device 101 through the interface module 231. For example, according to an embodiment of the disclosure, the image information may be received from the processor 120 (e.g., the main processor 121 (e.g., an application processor) or the auxiliary processor 123 (e.g., the graphic processing device) operated independently from the function of the main processor 121). The DDIC 230 may make communication with a touch circuit 250 or the sensor module 176 through the interface module 231. The DDIC 230 may store at least some of the received image information in the memory 233, for example, in unit of a frame. The image processing module 235 may perform pretreatment or post-treatment (e.g., adjusting a resolution, a brightness, or a size), with respect to, for example, at least some of the image data based at least on the characteristic of the image data or the characteristic of the display 210. The mapping module 237 may generate a voltage value or a current value corresponding to the image data subject to the pretreatment or the post-treatment through the image processing module 235. According to an embodiment of the disclosure, the voltage value and the current value may be generated based at least partially on attributes (e.g., the array (red green blue (RGB) stripe or pentile structure) of pixels or the size of each sub-pixel) of the display 210. At least some pixels of the display 201 may be driven based at least partially on, for example, the voltage value or the current value, such that visual information (e.g., a text, an image, or an icon) corresponding to the image data is displayed through the display 210.

According to an embodiment of the disclosure, the display module 160 may further include the touch circuit 250. The touch circuit 250 may include a touch sensor 251 and a touch sensor IC 253 for controlling the touch sensor 251. For example, the touch sensor IC 253 may control the touch sensor 251 to detect the touch input or the hovering input to a specified position of the display 210. For example, the touch sensor IC 253 may detect a touch input or a hovering input by measuring the change in the signal (e.g., a voltage, a light quantity, a resistance, or a charge amount) at a specific position of the display 210. The touch sensor IC 253 may provide, to the processor 120, information (e.g., a position, an area, pressure, or a time) on the detected touch input or hovering input. According to an embodiment of the disclosure, at least a portion (e.g., the touch sensor IC 253) of the touch circuit 250 may be included in a portion of the display driver IC 230 or the display 210, or a portion of another component (e.g., the auxiliary processor 123) disposed outside the display module 160.

According to an embodiment of the disclosure, the display module 160 may further include at least one sensor (e.g., a fingerprint sensor, an iris sensor, a pressure sensor, or an illuminance sensor) of the sensor module 176 or a control circuit for the at least one sensor. In this case, the at least one sensor or the control circuit for the at least one sensor may be embedded in a portion (e.g., the display 210 or the DDIC 230) of the display module 160 or a portion of the touch circuit 250. For example, when the sensor module 176 embedded in the display module 160 includes a biometric sensor (e.g., a fingerprint sensor), the biometric sensor may obtain biometric information (e.g., a fingerprint image) associated with a touch input through a partial area of the display 210. For another example, when the sensor module 176 embedded in the display module 160 includes a pressure sensor, the pressure sensor may obtain input information associated with the touch input through a partial area or the whole area of the display 210. According to an embodiment of the disclosure, the touch sensor 251 or the sensor module 176 may be disposed between pixels provided in a pixel layer or disposed on or under the pixel.

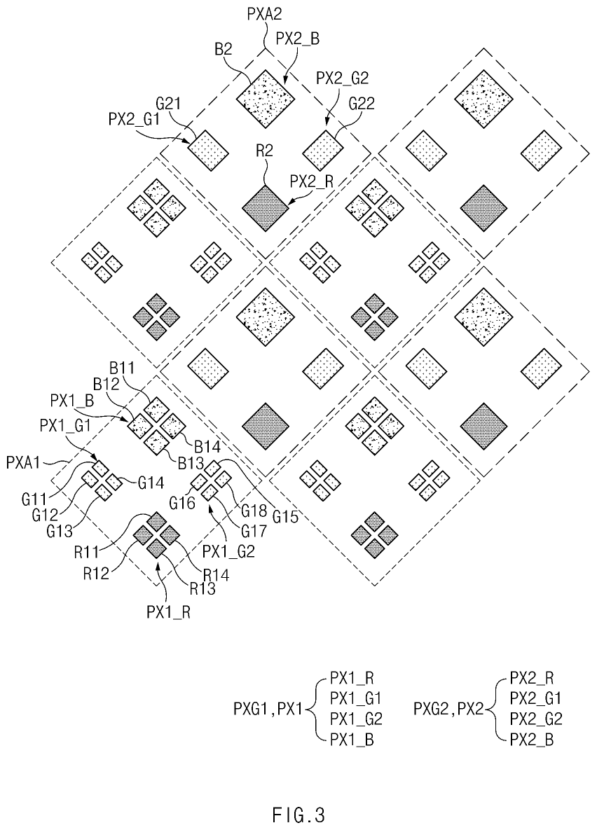

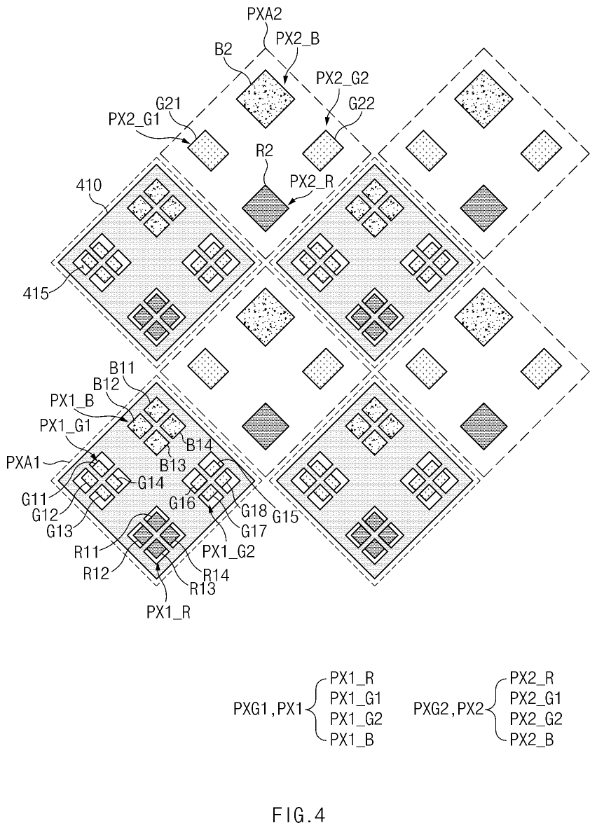

Hereinafter, some configurations included in a display of an electronic device according to an embodiment will be described with reference to FIGS. 3 and 4.

FIG. 3 is a view illustrating a plurality of pixels included in a display according to an embodiment of the disclosure. FIG. 4 is a view illustrating some configurations included in a display according to an embodiment of the disclosure.

Referring to FIGS. 3 and 4, the display included in the electronic device according to an embodiment may include a plurality of pixels PX1 and PX2 included in first pixel groups PXG1 and second pixel groups PXG2, and a light shielding member 410. The pixels PX1 and PX2 may be minimum units for displaying an image. One pixel PX1 and PX2 may be electrically connected to a data line that delivers a data voltage and a gate line that delivers a gate signal to emit light of a wavelength, which displays a specific color (e.g., any one of three primary colors).

In an embodiment of the disclosure, the first pixel group PXG1 may include at least one pixel PX1 of a first type. The at least one pixel PX1 of the first type of the first pixel group PXG1 may be disposed in an RGBG pentile structure. For example, the first pixel group PXG1 may include a red pixel PX1_R of the first type, green pixels PX1_G1 and PX1_G2 of the first type, and a blue pixel PX1_B of the first type. The first pixel group PXG1 may implement various colors by using red light, green light, and blue light emitted through the red pixel PX1_R of the first type, the green pixels PX1_G1 and PX1_G2 of the first type, and the blue pixel PX1_B of the first type.

In an embodiment of the disclosure, each of the pixels PX1 of the first type may include at least two light emitting areas R11, R12, R13, R14, G11, G12, G13, G14, G15, G16, G17, G18, B11, B12, B13, and B14 that are divided. The light emitting areas R11, R12, R13, R14, G11, G12, G13, G14, G15, G16, G17, G18, B11, B12, B13, and B14 may be areas, in which organic light emitting layers (e.g., first organic light emitting layers 1041 and 1042 and a second organic light emitting layer 1043) are located to emit light.

In an embodiment of the disclosure, the red pixel PX1_R of the first type may include a plurality of red light emitting areas R11, R12, R13, and R14 that are spaced apart from each other. The plurality of red light emitting areas R11, R12, R13, and R14 included in the one red pixel PX1_R of the first type may emit light based on the same data voltage and the same gate signal. For example, the plurality of red light emitting areas R11, R12, R13, and R14 included in the one red pixel PX1_R of the first type may overlap the same pixel electrode. The number and disposition of the plurality of red light emitting areas R11, R12, R13, and R14 are not limited to those illustrated in FIGS. 3 and 4.

In an embodiment of the disclosure, the green pixels PX1_G1 and PX1_G2 of the first type may include a plurality of green light emitting areas G11, G12, G13, G14, G15, G16, G17, and G18 that are spaced apart from each other. The plurality of green light emitting areas G11, G12, G13, and G14 included in the one green pixel PX1_G1 of the first type may emit light based on the same data voltage and the same gate signal. For example, the plurality of green light emitting areas G11, G12, G13, and G14 included in the one green pixel PX1_G1 of the first type may overlap the same pixel electrode. The plurality of green light emitting areas G15, G16, G17, and G18 included in the one green pixel PX1_G2 of the first type may emit light based on the same data voltage and the same gate signal. For example, the plurality of green light emitting areas G15, G16, G17, and G18 included in another green pixel PX1_G2 of the first type may overlap the same pixel electrode. The number and disposition of the plurality of green light emitting areas G11, G12, G13, G14, G15, G16, G17, and G18 are not limited to those illustrated in FIGS. 3 and 4. FIGS. 3 and 4 illustrate that two green pixels PX1_G1 and PX1_G2 of the first type are included, but the first pixel group PXG1 may include one green pixel of the first type according to an embodiment.

In an embodiment of the disclosure, the blue pixel PX1_B of the first type may include a plurality of blue light emitting areas B11, B12, B13, and B14 that are spaced apart from each other. The plurality of blue light emitting areas B11, B12, B13, and B14 included in the one blue pixel PX1_B of the first type may emit light based on the same data voltage and the same gate signal. For example, the plurality of blue light emitting areas B11, B12, B13, and B14 included in the one blue pixel PX1_B of the first type may overlap the same pixel electrode. The number and disposition of the plurality of blue light emitting areas B11, B12, B13, and B14 are not limited to those illustrated in FIGS. 3 and 4.

According to an embodiment of the disclosure, the pixel PX1 of the first type may not include two or more light emitting areas that are divided, but may include one light emitting area that is not divided, and in this case, an angle of view may be restricted by using the light shielding member 410, which will be described below.

In an embodiment of the disclosure, the second pixel group PXG2 may include at least one pixel PX2 of a second type. The at least one pixel PX2 of the second type of the second pixel group PXG2 may be disposed in an RGBG pentile structure. For example, the second pixel group PXG2 may include a red pixel PX2_R of the second type, green pixels PX2_G1 and PX2_G2 of the second type, and a blue pixel PX2_B of the second type. The second pixel group PXG2 may implement various colors by using red light, green light, and blue light emitted through the red pixel PX2_R of the second type, the green pixels PX2_G1 and PX2_G2 of the second type, and the blue pixel PX2_B of the second type. The red pixel PX2_R of the second type may include one red light emitting area R2 that is not divided. The green pixel PX2_G1 and PX2_G2 of the second type may include one green light emitting area G21 and G22 that is not divided. The blue pixel PX2_B of the second type may include one blue light emitting area B2 that is not divided.

In an embodiment of the disclosure, the first pixel groups PXG1 and the second pixel groups PXG2 may be alternately disposed. The display according to an embodiment may display an image by using both of the first pixel groups PXG1 and the second pixel groups PXG2 when being operated in a normal mode. The display according to an embodiment may switch off the second pixel groups PXG2 and display an image by using only the first pixel groups PXG1 when being operated in an angle-of-view restricting mode (a private mode). An angle of view in the angle-of-view restricting mode may be smaller than an angle of view in the normal mode. The angle of view may mean a maximum angle of a side surface, by which a normal screen is recognized with reference to a front surface. FIGS. 3 and 4 illustrate an example of disposition of the first pixel groups PXG1 and the second pixel groups PXG2, and the disposition of the first pixel groups PXG1 and the second pixel groups PXG2 is not limited to those illustrated in FIGS. 3 and 4.

In an embodiment of the disclosure, the light shielding member 410 may be located in a first pixel area PXA1. The first pixel area PXA1 may be an area, in which the first pixel groups PXG1 are located. The first pixel area PXA1 may include the light emitting areas R11, R12, R13, R14, G11, G12, G13, G14, G15, G16, G17, G18, B11, B12, B13, and B14 of the pixels PX1 of the first type, and peripheral areas. The light shielding member 410 may not be located in a second pixel area PXA2. The second pixel area PXA2 may be an area, in which the second pixel groups PXG2 are located. The second pixel area PXA2 may include the light emitting areas R2, G21, G22, and B2 of the pixels PX2 of the second type, and peripheral areas.

In an embodiment of the disclosure, the light shielding member 410 may include a plurality of openings 415. The plurality of openings 415 of the light shielding member 410 may be aligned with the light emitting areas R11, R12, R13, R14, G11, G12, G13, G14, G15, G16, G17, G18, B11, B12, B13, and B14 of the first pixel groups PXG1. The light shielding member 410 may not overlap the light emitting areas R11, R12, R13, R14, G11, G12, G13, G14, G15, G16, G17, G18, B11, B12, B13, and B14 of the first pixel groups PXG1. The light shielding member 410 may be located on the first pixel groups PXG1 to surround the light emitting areas R11, R12, R13, R14, G11, G12, G13, G14, G15, G16, G17, G18, B11, B12, B13, and B14 of the first pixel groups PXG1 to restrict the angles of view of the pixels PX1 of the first type of the first pixel groups PXG1 within a specific range. The light shielding member 410 may not overlap the peripheral areas of the light emitting areas R2, G21, G22, and B2 of the second pixel groups PXG2.

Unlike those illustrated, when each of the pixels PX1 of the first type does not include the divided light emitting areas but includes one light emitting area, the light shielding member 410 may be located on the pixels PX1 of the first type to surround the light emitting area of each of the pixels PX1 of the first type, which is not divided.

According to an embodiment of the disclosure, FIGS. 3 and 4 illustrate that each of the pixels PX1 of the first type has four light emitting areas R11, R12, R13, R14, G11, G12, G13, G14, G15, G16, G17, G18, B11, B12, B13, and B14, but each of the pixels PX1 of the first type may have two light emitting areas or light emitting areas of various forms and numbers. Furthermore, a shape and/or a size of each of the pixels PX1_R, PX1_G1, PX1_G2, and PX1_B of the first type may be different from a shape and/or a size of each of the pixels PX2_R, PX2_G1, PX2_G2, and PX2_B of the second type, and for example, an area of each of the blue light emitting areas B11, B12, B13, and B14 of the blue pixel PX1_B of the first type may be made larger than one fourth of an area of the blue light emitting area B2 of the blue pixel PX2_B of the second type to increase a life span of the pixel.

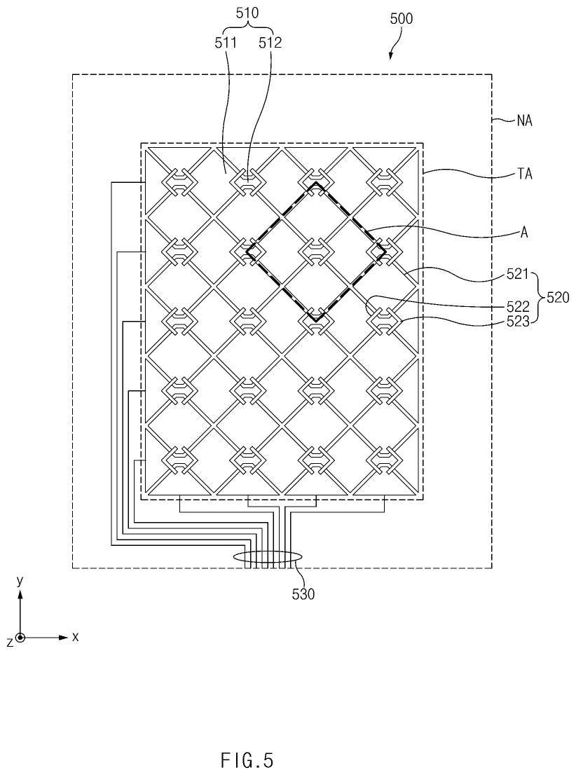

FIG. 5 is a schematic plan view of a touch sensing layer included in a display according to an embodiment of the disclosure.

Referring to FIG. 5, a touch sensing layer 500 may include a plurality of first touch electrodes 510, a plurality of second touch electrodes 520, and a plurality of wiring lines 530.

In an embodiment of the disclosure, each of the first touch electrodes 510 may include a plurality of first touch cells 511 having a rhombus shape, and a plurality of first connection members 512 that connect the first touch cells 511 that are adjacent to each other along an x direction. The first touch electrode 510 may be a Tx touch electrode (transmitter touch electrode), to which a first touch signal (e.g., a Tx signal) is delivered. It has been described that the first touch cells have a rhombus shape, but the shape of the first touch cells 511 is not limited thereto.

In an embodiment of the disclosure, each of the second touch electrodes 520 may include a plurality of second touch cells 521 having a rhombus shape, and a plurality of second connection members 522 and a plurality of third connection members 523, which electrically connect the second touch cells 521 that are adjacent to each other along an y direction. The second connection members 522 and the third connection members 523 together may electrically connect one second touch cell 521 and another second touch cell 521. The second touch electrode 520 may be a Rx touch electrode (receiver touch electrode), to which a second touch signal (e.g., an Rx signal) is delivered. It has been described that the second touch cells have a rhombus shape, but the shape of the second touch cells 521 is not limited thereto.

In an embodiment of the disclosure, the first touch electrodes 510 and the second touch electrodes 520 may be spaced apart from each other by a specific interval, and electrostatic capacitance may be formed between the first touch electrodes 510 and the second touch electrodes 520. Based on a touch by a user, the electrostatic capacitance formed between the first touch electrodes 510 and the second touch electrodes 520 may be changed, and the electronic device may detect a touch location by recognizing the change in the electrostatic capacitance.

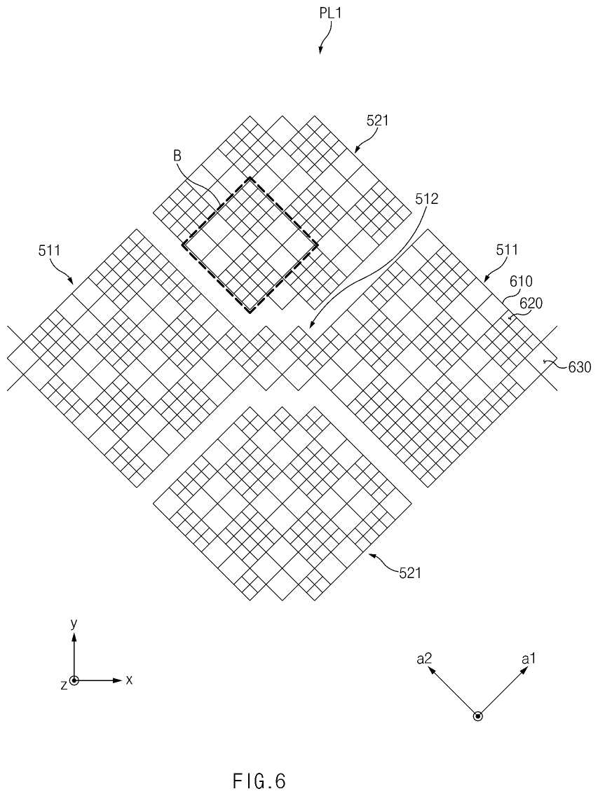

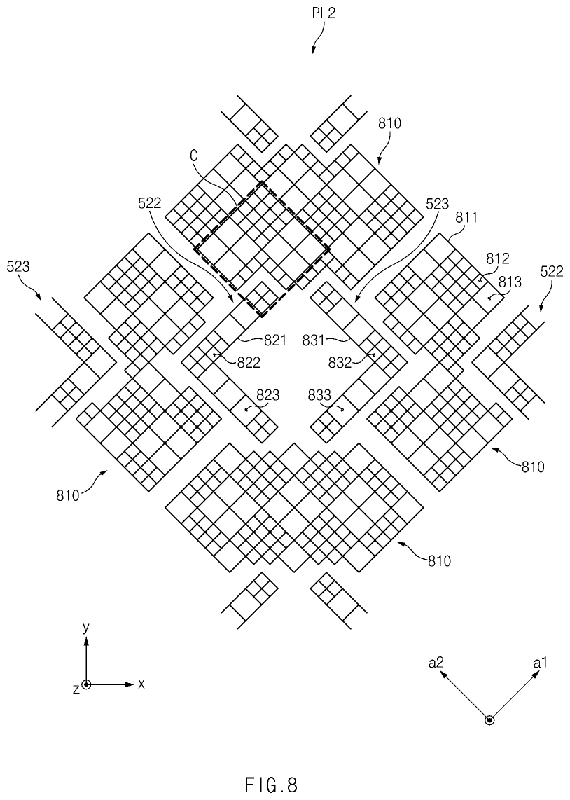

In an embodiment of the disclosure, the first touch cells 511, the second touch cells 521, and the first connection members 512 may be located in the same layer. For example, the first touch cells 511, the second touch cells 521, and the first connection members 512 may be located in the first touch pattern layer (e.g., a first touch pattern layer PL1 of FIG. 6). The second connection members 522 and the third connection members 523 may be located on layers that are different from those of the first touch cells 511, the second touch cells 521, and the first connection members 512. For example, the second connection members 522 and the third connection members 523 may be located in the second touch pattern layer (e.g., a second touch pattern layer PL2 of FIG. 8). An insulation layer may be located between the first touch pattern layer and the second touch pattern layer. The second connection members 522 and the third connection members 523 may be connected to the second touch cells 521 through contact holes formed in the insulation layer.

In an embodiment of the disclosure, the first touch electrodes 510 and the second touch electrodes 520 may include an opaque conductive material. For example, the first touch electrodes 510 and the second touch electrodes 520 may include a structure, in which a titanium (Ti) layer, an aluminum (Al) layer, and a titanium (Ti) layer are laminated.

In an embodiment of the disclosure, the first touch cells 511 and the first connection members 512 of the first touch electrodes 510 may be integrally formed. Accordingly, the first touch cells 511 and the first connection members 512 may be formed simultaneously in the same process operation. However, the first connection members 512 are not necessarily formed simultaneously when the first touch cells 511 are formed, and may be formed separately in another process operation by using another material.

Furthermore, although it has been described that the second connection members 522 and the third connection members 523 are located on a layer that is different from the layers of the first touch cells 511, the second touch cells 521, and the first connection members 512, but the disclosure is not necessarily limited thereto, and the first touch cells 511, the second touch cells 521, the second connection members 522, and the third connection members 523 may be located on the same layer, and the first connection members 512 may be located on a layer that is different from the layers of the first touch cells 511, the second touch cells 521, the second connection members 522, and the third connection members 523.

Furthermore, according to an embodiment of the disclosure, the first touch cells 511 and the first connection members 512 of the first touch electrodes 510 may be located in the same layer, the second touch cells 521, the second connection members 522, and the third connection members 523 of the second touch electrodes 520 may be located in the same layer, and the first touch electrodes 510 and the second touch electrodes 520 may be located on different layers.

In an embodiment of the disclosure, the plurality of wiring lines 530 may be connected to the first touch electrodes 510 or the second touch electrodes 520 to deliver a touch signal. The first touch electrodes 510 and the second touch electrodes 520 may be located in a touch active area TA that detects a touch, and the plurality of wiring lines 530 may be located in a touch non-active area NA on an outside of the touch active area TA. According to an embodiment of the disclosure, the touch sensing layer 500 may further include a dummy touch pattern, in which a touch signal is not delivered, in the touch non-active area NA.

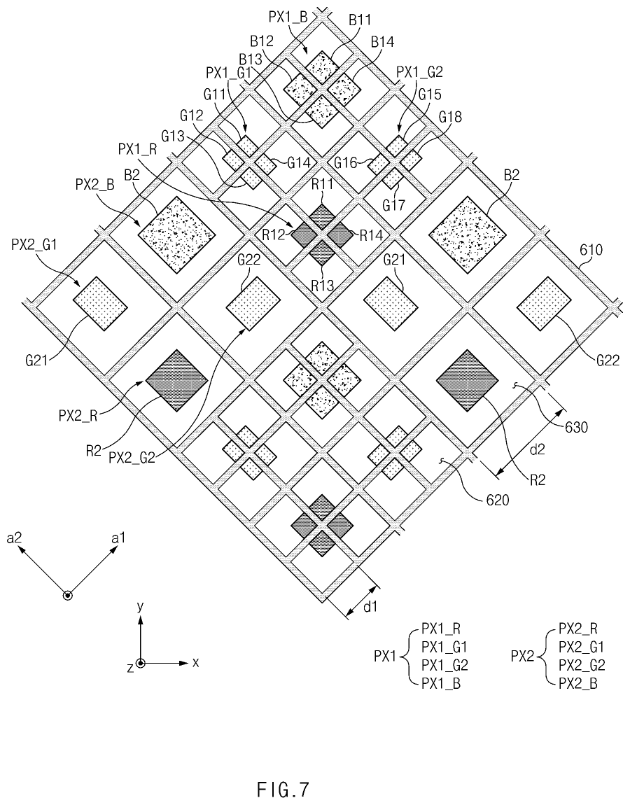

Hereinafter, disposition of the first touch pattern layer PL1 and the pixels will be described with reference to FIGS. 6 and 7.

FIG. 6 is a plan view illustrating a first touch pattern layer PL1 of area “A” of FIG. 5 according to an embodiment of the disclosure.

FIG. 7 is an enlarged view illustrating area “B” of FIG. 6 according to an embodiment of the disclosure.

Referring to FIGS. 6 and 7, in an embodiment of the disclosure, the first touch pattern layer PL1 may include the first touch cells 511 and the first connection members 512 of the first touch electrodes 510, and the second touch cells 521 of the second touch electrodes 520. The first touch cells 511, the second touch cells 521, and the first connection members 512 of the first touch pattern layer PL1 may include a mesh pattern. The first touch cells 511, the second touch cells 521, and the first connection members 512 may include a plurality of unit pattern lines 610 that extend in one direction a1 and another direction a2 that crosses the one direction a1, and has a fine width. The unit pattern lines 610 of the first touch cells 511, the second touch cells 521, and the first connection members 512 of the first touch pattern layer PL1 may deliver a touch signal.

In an embodiment of the disclosure, the unit pattern lines 610 may be located at least one of between the plurality of pixels PX1 and PX2, between the light emitting areas R11, R12, R13, R14, G11, G12, G13, G14, G15, G16, G17, G18, B11, B12, B13, and B14 of the pixel PX1 of the first type, and between the light emitting areas R2, G21, G22, and B2 of the pixel PX2 of the second type. The unit pattern lines 610 may not overlap the light emitting areas R11, R12, R13, R14, G11, G12, G13, G14, G15, G16, G17, G18, B11, B12, B13, and B14 of the pixel PX1 of the first type and the light emitting areas R2, G21, G22, and B2 of the pixel PX2 of the second type in the z direction.

In an embodiment of the disclosure, the unit pattern lines 610 may cross each other perpendicularly to define openings 620 and 630 of a rhombus shape. The mesh patterns of the first touch cells 511, the second touch cells 521, and the first connection members 512 may have a specific lattice shape along the arrangement of the unit pattern lines 610. The openings 620 and 630 between the unit pattern lines 610 of the first touch cells 511, the second touch cells 521, and the first connection members 512 may include the first opening 620 aligned with the light emitting areas R11, R12, R13, R14, G11, G12, G13, G14, G15, G16, G17, G18, B11, B12, B13, and B14 of the pixel PX1 of the first type in the z direction, and the second opening 630 aligned with the light emitting areas R2, G21, G22, and B2 of the pixel PX2 of the second type in the z direction. The first opening 620 may be aligned with the light emitting areas R11, R12, R13, R14, G11, G12, G13, G14, G15, G16, G17, G18, B11, B12, B13, and B14 of the pixel PX1 of the first type in the z direction such that the light emitted from the light emitting areas R11, R12, R13, R14, G11, G12, G13, G14, G15, G16, G17, G18, B11, B12, B13, and B14 may travel to an outside of the display through the first opening 620. The second opening 630 may be aligned with the light emitting areas R2, G21, G22, and B2 of the pixel PX2 of the second type in the z direction such that the light emitting from the light emitting areas R2, G21, G22, and B2 may travel to an outside of the display through the second opening 630.

In an embodiment of the disclosure, a distance d1 between two unit patterns 610 that are adjacent to each other while one light emitting area R11, R12, R13, R14, G11, G12, G13, G14, G15, G16, G17, G18, B11, B12, B13, or B14 of the pixel PX1 of the first type is interposed therebetween may be smaller than a distance d2 between two unit pattern lines 610 that are adjacent to each other while one light emitting area R2, G21, G22, or B2 of the pixel PX2 of the second type is interposed therebetween. For example, the width d1 of the first opening 620 may be smaller than the width d2 of the second opening 630. An area of the first opening 620 may be smaller than an area of the second opening 630.

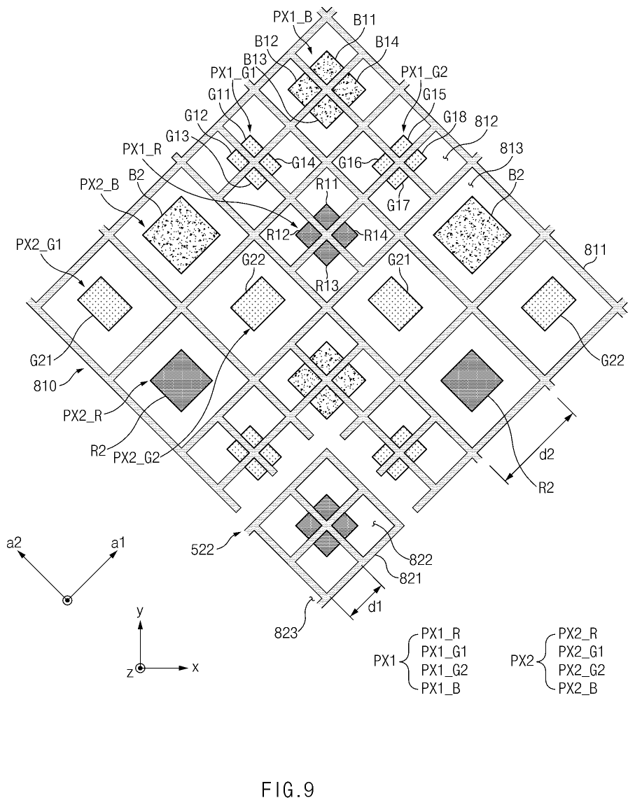

Hereinafter, disposition of the second touch pattern layer PL2 and the pixels will be described with reference to FIGS. 8 and 9.

FIG. 8 is a plan view illustrating a second touch pattern layer PL2 of area “A” of FIG. 5 according to an embodiment of the disclosure.

FIG. 9 is an enlarged view illustrating area “C” of FIG. 8 according to an embodiment of the disclosure.

Referring to FIGS. 8 and 9, in an embodiment of the disclosure, the second touch pattern layer PL2 may include the second connection members 522, the third connection members 523, and a light shielding pattern 810. The second connection members 522, the third connection members 523, and the light shielding pattern 810 may be spaced apart from each other. The light shielding pattern 810 may be a pattern that is formed in an area, in which the second connection members 522 and the third connection members 523 are not located, not to be connected to the second connection members 522 and the third connection members 523. The light shielding pattern 810 may float not to deliver an electric signal.

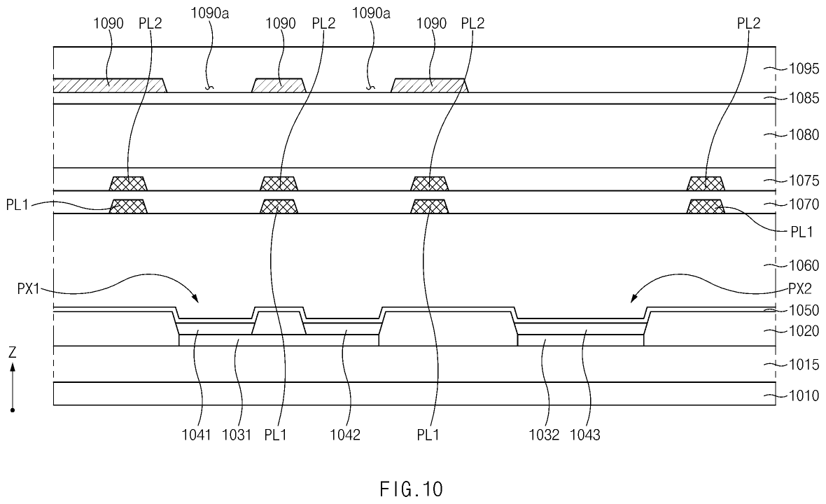

In an embodiment of the disclosure, the second connection members 522, the third connection members 523, and the light shielding pattern 810 of the second touch pattern layer PL2 may include a mesh pattern. The second connection members 522, the third connection members 523, and the light shielding pattern 810 of the second touch pattern layer PL2 may include a plurality of unit pattern lines 811, 821, and 831 that cross each other. The unit pattern lines 811, 821, and 831 of the second touch pattern layer PL2 may overlap the unit pattern lines 610 of the first touch pattern layer PL1 in the z direction. The unit pattern lines 821 of the second connection members 522 and the unit pattern lines 831 of the third connection members 523 may be electrically connected to the second touch cells 521 to deliver a touch signal. For example, the second touch cells 521 of the first touch pattern layer PL1 and the unit pattern lines 821 of the second connection members 522 of the second touch pattern layer PL2 and the unit pattern lines 831 of the third connection members 523 may be connected to each other through a connection hole (a via) formed in an insulation layer (e.g., an insulation layer 1070 of FIG. 10). For example, a photolithography process using a plurality of photo mask and an etching process may be formed on the first touch pattern layer PL1 and the insulation layer (e.g., the insulation layer 1070 of FIG. 10), and a transparent conductive material related to the second touch pattern layer PL2 may be filled in the connection hole of the insulation layer (e.g., the insulation layer 1070 of FIG. 10) formed therethrough. The unit pattern line 811 of the light shielding pattern 810 may not deliver an electric signal.

In an embodiment of the disclosure, the unit pattern lines 811, 821, and 831 may be located at least one of between the plurality of pixels PX1 and PX2, between the light emitting areas R11, R12, R13, R14, G11, G12, G13, G14, G15, G16, G17, G18, B11, B12, B13, and B14 of the pixel PX1 of the first type, and between the light emitting areas R2, G21, G22, and B2 of the pixel PX2 of the second type. The unit pattern lines 811, 821, and 831 may not overlap the light emitting areas R11, R12, R13, R14, G11, G12, G13, G14, G15, G16, G17, G18, B11, B12, B13, and B14 of the pixel PX1 of the first type and the light emitting areas R2, G21, G22, and B2 of the pixel PX2 of the second type in the z direction.

In an embodiment of the disclosure, the unit pattern lines 811, 821, and 831 may cross each other perpendicularly to define openings 812, 813, 822, 823, 832, and 833 of a rhombus shape. The openings 812, 813, 822, 823, 832, and 833 between the unit pattern lines 811, 821, and 831 may include the first openings 812, 822, and 832 aligned with the light emitting areas R11, R12, R13, R14, G11, G12, G13, G14, G15, G16, G17, G18, B11, B12, B13, and B14 of the pixel PX1 of the first type in the z direction, and the second openings 813, 823, and 833 aligned with the light emitting areas R2, G21, G22, and B2 of the pixel PX2 of the second type in the z direction.

In an embodiment of the disclosure, the distance d1 between two unit patterns 811, 821, and 831 that are adjacent to each other while one light emitting area R11, R12, R13, R14, G11, G12, G13, G14, G15, G16, G17, G18, B11, B12, B13, or B14 of the pixel PX1 of the first type is interposed therebetween may be smaller than the distance d2 between two unit pattern lines 811, 821, and 831 that are adjacent to each other while one light emitting area R2, G21, G22, or B2 of the pixel PX2 of the second type is interposed therebetween. For example, the width d1 of the first opening 812, 822, and 832 may be smaller than the width d2 of the second opening 813, 823, and 833. An area of the first opening 812, 822, or 832 may be smaller than an area of the second opening 813, 823, or 833.

According to an embodiment of the disclosure, the unit pattern lines 610 of FIGS. 6 and 7 and the unit pattern lines 811, 821, and 831 of FIGS. 8 and 9 may be formed of a transparent conductive material or may be formed of a low-resistance metal material, such as molybdenum (Mo), silver (Ag), titanium (Ti), copper (Cu), aluminum (Al), or molybdenum/aluminum/molybdenum (Mo/Al/Mo). According to an embodiment of the disclosure, the low-resistance metal material may be patterned through the photolithography process using the photo masks (not illustrated) and the etching process.

Hereinafter, a cross-sectional structure of the display included in the electronic device according to an embodiment will be described with reference to FIG. 10.

FIG. 10 is a cross-sectional view of an area of a display included in an electronic device according to an embodiment of the disclosure.

Referring to FIG. 10, the display according to an embodiment may include a board 1010, a pixel circuit layer 1015, a pixel definition layer (PDL) 1020, a first pixel electrode 1031 (e.g., an anode), a second pixel electrode 1032 (e.g., an anode), the first organic light emitting layers 1041 and 1042, the second organic light emitting layer 1043, a common electrode 1050 (e.g., a cathode), an encapsulation layer 1060, the first touch pattern layer PL1, the insulation layer 1070, the second touch pattern layer PL2, a planarization layer 1075, an optical layer 1080, a protection layer 1085, a light shielding member 1090, and an over-coating layer 1095.

Although FIG. 10 illustrates that the first touch pattern layer PL1 and the second touch pattern layer PL2 overlap each other in the z direction according to an embodiment of the disclosure, at least a portion of the first touch pattern layer PL1 may not overlap the second touch pattern layer PL2 according to the embodiment. For example, the first touch pattern layer PL1 may be located on the pixel definition layer 1020 in the z direction, but the second touch pattern layer PL2 may not be located on the first touch pattern layer PL1 on the z direction.

In an embodiment of the disclosure, the board 1010 may be a flexible board. The board 1010 may be formed of plastic, such as polyimide (PI), polyethylene terephthalate (PET), polyethylene napthalate (PEN), polycarbonate (PC), polyarylate (PAR), polyetherimide (PEI), and polyethersulphone (PES), which has an excellent heat-resistant property and an excellent durability. However, various embodiments of the disclosure are not limited thereto, and various flexible materials, such as metal foil or thin glass may be used. Meanwhile, the board 1010 may be a rigid board, and then, the board 1010 may be formed of a glass material, a main substance of which is SiO₂.

In an embodiment of the disclosure, the pixel circuit layer 1015 may be located on a z direction side of the board 1010. The pixel circuit layer 1015 may include a plurality of wiring lines that deliver a signal for driving the pixels and a plurality of thin film transistors.

In an embodiment of the disclosure, the pixel definition layer 1020 may be located on the z direction side of the pixel circuit layer 1015, and may include openings, in which the organic light emitting layers 1041, 1042, and 1043 are located to divide the light emitting areas. The pixel definition layer 1020 may include openings which expose the first pixel electrode 1031 and the second pixel electrode 1032, and in which the organic light emitting layers 1041, 1042, and 1043 are located. The pixel definition layer 1020 may be disposed to surround the first organic light emitting layers 1041 and 1042 of the pixel PX1 of the first type and the second organic light emitting layer 1043 of the pixel PX2 of the second type. The pixel definition layer 1020 may also be located on a z direction side of the first pixel electrode 1031 to overlap at least a partial area of the first pixel electrode 1031, and may divide the first organic light emitting layers 1041 and 1042 of the pixel PX1 of the first type into two or more areas. The pixel definition layer 1020 may include an organic material or a silica-based inorganic material.

In an embodiment of the disclosure, the first pixel electrode 1031 and the second pixel electrode 1032 may be located on a z direction side of the pixel circuit layer 1015.

In an embodiment of the disclosure, the first organic light emitting layers 1041 and 1042 may be located on the z direction side of the first pixel electrode 1031 exposed through the openings of the pixel definition layer 1020. The second organic light emitting layer 1043 may be located on the z direction side of the second pixel electrode 1032 exposed through the openings of the pixel definition layer 1020. The first organic light emitting layers 1041 and 1042 may include the first sub-organic light emitting layer 1041 and the second sub-organic light emitting layer 1042 divided by the pixel definition layer 1020. The first sub-organic light emitting layer 1041 and the second sub-organic light emitting layer 1042, which are spaced apart from each other, may overlap the first pixel electrode 1031 in the z direction. Each of the first organic light emitting layers 1041 and 1042 and the second organic light emitting layer 1043 may emit light of, among red, green, and blue, any one color. The areas, in which the first organic light emitting layers 1041 and 1042 are located, may correspond to the light emitting areas (e.g., the light emitting areas R11, R12, R13, R14, G11, G12, G13, G14, G15, G16, G17, G18, B11, B12, B13, and B14 of FIG. 3) of the pixel PX1 of the first type. The area, in which the second organic light emitting layer 1043 is located, may correspond to the light emitting areas (e.g., the light emitting areas R2, G21, G22, and B2 of FIG. 3) of the pixel PX2 of the second type.

In an embodiment of the disclosure, the common electrode 1050 may be located on a z direction side of the pixel definition layer 1020, the first organic light emitting layers 1041 and 1042, and the second organic light emitting layer 1043. The common electrode 1050 may be located over the plurality of pixels PX1 and PX2. The first pixel electrode 1031, the first organic light emitting layers 1041 and 1042, and the common electrode 1050 may constitute one organic light emitting diode (OLED), and the second pixel electrode 1032, the second organic light emitting layer 1043, and the common electrode 1050 may constitute one organic light emitting diode (OLED).

In an embodiment of the disclosure, the encapsulation layer 1060 may be located on a z direction side of the common electrode 1050. The encapsulation layer 1060 may cover and seal the organic light emitting diode (OLED). The encapsulation layer 1060 may seal the organic light emitting diode (OLED) to interrupt introduction of external moisture and oxygen. The encapsulation layer 1060 may include a plurality of layers, and may include a triple layer, in which an inorganic film, an organic film, and an inorganic film are sequentially laminated. In an embodiment of the disclosure, the encapsulation layer 1060 may include a plurality of inorganic films and a plurality of organic films. For example, the inorganic films and the organic films may be laminated alternately. For example, at least one inorganic film may be formed on a z direction side of the encapsulation layer 1060 or between the encapsulation layer 1060 and the first touch pattern layer PL1. The at least one inorganic film may include a metal oxide, a metal nitride, a metal carbide, or a combination thereof. As another example, the inorganic film may include an aluminum oxide, a silicon oxide, or a silicon nitride. According to another embodiment of the disclosure, the inorganic films may include a lamination structure of a plurality of inorganic insulation layers. In an embodiment of the disclosure, the first touch pattern layer PL1 may be located on the z direction side of the encapsulation layer 1060. The first touch pattern layer PL1 may overlap the pixel definition layer 1020 in the z direction. The first touch pattern layer PL1 may not overlap the first organic light emitting layers 1041 and 1042 and the second organic light emitting layer 1043 in the z direction. At least a portion of the first touch pattern layer PL1 may overlap the pixel definition layer 1020 located between the first sub-organic light emitting layer 1041 and the second sub-organic light emitting layer 1042 and the first pixel electrode 1031 in the z direction.

In an embodiment of the disclosure, the insulation layer 1070 (e.g., the inter-layer dielectric (ILD)) may be located on the z direction side of the first touch pattern layer PL1. The insulation layer 1070 may be formed in a scheme of depositing an inorganic film by using a plasma enhanced chemical vapor deposition (PECVD) method. The insulation layer 1070 may function as a spacer that maintains a spacing interval between the first touch pattern layer PL1 and the second touch pattern layer PL2. Accordingly, the insulation layer 1070 may be transparent, and may be formed of an inorganic film having an excellent heat-resistant property, an excellent chemical-resistant property, an excellent electrically insulating property, and an excellent elasticity. For example, the insulation layer 1070 may be formed of a silicon oxide film, a silicon nitride film, or a multilayer thereof.

In an embodiment of the disclosure, the second touch pattern layer PL2 may be located on the z direction side of the insulation layer 1070. The second touch pattern layer PL2 may overlap the pixel definition layer 1020 in the z direction. The second touch pattern layer PL2 may not overlap the first organic light emitting layers 1041 and 1042 and the second organic light emitting layer 1043 in the z direction. At least a portion of the second touch pattern layer PL2 may overlap the pixel definition layer 1020 located between the first sub-organic light emitting layer 1041 and the second sub-organic light emitting layer 1042 and the first pixel electrode 1031 in the z direction.

According to an embodiment of the disclosure, the first touch pattern layer PL1 and the second touch pattern layer PL2 may be formed of a transparent conductive oxide. Examples of the transparent conductive oxide may include an indium tin oxide (ITO), an indium zinc oxide (IZO), a zinc oxide (ZNO), an indium oxide (In₂O3), an indium gallium oxide (IGO), an aluminum zinc oxide (AZO).

According to an embodiment of the disclosure, one of the plurality of inorganic films that constitute the encapsulation layer 1060 may be used as the insulation layer related to the touch pattern layers (e.g., the first touch pattern layer PL1 and the second touch pattern layer PL2). Through this, the manufacturing process may be simplified and a thickness of the display may become thinner.

In an embodiment of the disclosure, the planarization layer 1075 may be located on the z direction side of the second touch pattern layer PL2. The planarization layer 1075 may include an organic material, such as an acryl-based resin, and may planarize a surface of a layer, in which the second touch pattern layer PL2 is located. For example, the planarization layer 1075 may include a polymeric organic compound, and may function to alleviate internal stresses of the inorganic films, or supplement and planarize defects of the inorganic films.

In an embodiment of the disclosure, the planarization layer 1075 may include an inorganic insulation film (e.g., a silicon oxide (SiO₂)) and/or an organic insulation film (e.g., a general-purpose polymer (PMMA or PS). For example, the first touch pattern layer PL1, the insulation layer 1070, and the second touch pattern layer PL2 may be used as the touch sensor (e.g., the touch sensor 251 of FIG. 2) by applying a passivation film. Furthermore, the passivation film may be formed with a complex lamination structure of the inorganic insulation film and the organic insulation film.

In an embodiment of the disclosure, the optical layer 1080 may be located on a z direction side of the planarization layer 1075. For example, the optical layer 1080 may include a material having a refractive index that is larger than a refractive index of an adjacent layer. The electronic device according to an embodiment may include the optical layer 1080 to cause a travel path of the light emitted from the first organic light emitting layers 1041 and 1042 to face a z direction side, and an angle of view of the pixel PX1 of the first pattern may be effectively restrained. For example, a light outputting efficiency may be enhanced by reducing a Fresnel reflection ratio, by which a portion of the light that faces an outside is reflected on a border surface with external air and returns to an interior of the display, and improving a light transmission ratio.

In another embodiment of the disclosure, the optical layer 1080 may include a coating layer, on which a material having a high refractive index is coated, and a coating layer, on which a material having a low refractive index is coated, and the coating layers may be disposed in multiple layers while crossing each other. For example, the coating layer coated with the material having the high refractive index may have a refractive index of about not less than 1.70 and not more than 2.80 or about not less than 1.90 and not more than 2.80, and the coating layer coated with the material having the low refractive index may have a refractive index of about not less than 1.20 and not more than 1.50.

In an embodiment of the disclosure, the protection layer 1085 may be located on a z direction side of the optical layer 1080.

In an embodiment of the disclosure, the light shielding member 1090 (e.g., a black mask) may be located on a z direction side of the protection layer 1085 to surround peripheries of the first organic light emitting layers 1041 and 1042 of the pixel PX1 of the first type. The light shielding members 1090 may include openings 1090a aligned with the first sub-organic light emitting layer 1041 and the second sub-organic light emitting layer 1042, respectively. The light shielding member 1090 may shield light while not transmitting the light. The light shielding member 1090 may be disposed to overlap the pixel definition layer 1020 that is adjacent to the first organic light emitting layers 1041 and 1042 in the z direction. At least a portion of the light shielding member 1090 may overlap the pixel definition layer 1020 located between the first sub-organic light emitting layer 1041 and the second sub-organic light emitting layer 1042 in the z direction. Furthermore, at least a portion of the light shielding member 1090 may overlap the first touch pattern layer PL1, the second touch pattern layer PL2, and the first pixel electrode 1031 in the z direction. The electronic device according to an embodiment may include the light shielding member 1090 located at peripheral portions of the first sub-organic light emitting layer 1041 and the second sub-organic light emitting layer 1042, and the first touch pattern layer PL1 and the second touch pattern layer PL2 that overlap the light shielding member 1090 to shield the light that travels between the light shielding member 1090 and the pixel definition layer 1020.

In an embodiment of the disclosure, the over-coating layer 1095 (e.g., an overcoat) may be located on the z direction side of the light shielding member 1090. The over-coating layer 1095 may include an organic insulation film. Furthermore, the over-coating layer 1095 may include the complex lamination structure of the inorganic insulation film and the organic insulation film.

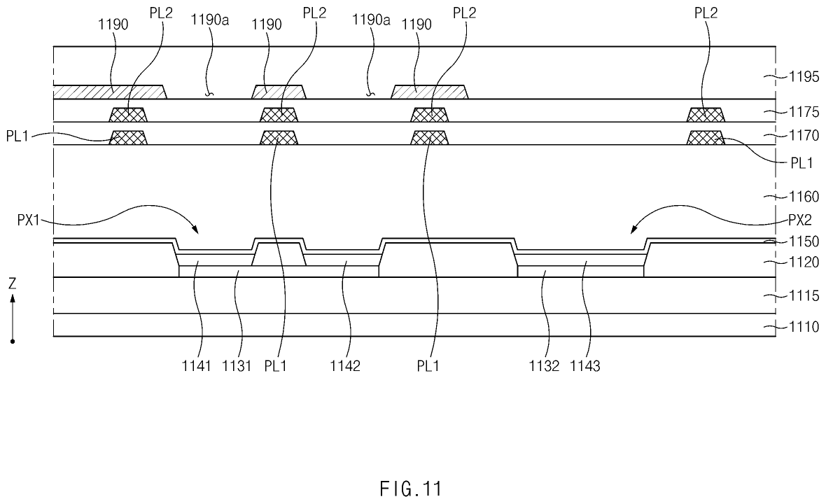

Hereinafter, a cross-sectional structure of the display included in the electronic device according to an embodiment will be described with reference to FIG. 11.

FIG. 11 is a cross-sectional view of an area of a display included in an electronic device according to an embodiment of the disclosure.

Referring to FIG. 11, the display according to an embodiment of the disclosure may include a board 1110, a pixel circuit layer 1115, a pixel definition layer (PDL) 1120, a first pixel electrode 1131, a second pixel electrode 1132, first organic light emitting layers 1141 and 1142, a second organic light emitting layer 1143, a common electrode 1150, an encapsulation layer 1160, the first touch pattern layer PL1, an insulation layer 1170, the second touch pattern layer PL2, a planarization layer 1175, a light shielding member 1190, and an over-coating layer 1195.

In an embodiment of the disclosure, the pixel circuit layer 1115 may be located on a z direction side of the board 1110. The pixel circuit layer 1115 may include a plurality of wiring lines that deliver a signal for driving the pixels and a plurality of thin film transistors.

In an embodiment of the disclosure, the pixel definition layer 1120 may be located on the z direction side of the pixel circuit layer 1115, and may include openings, in which the organic light emitting layers 1141, 1142, and 1143 are located to divide the light emitting areas. The pixel definition layer 1120 may include openings which expose the first pixel electrode 1131 and the second pixel electrode 1132, and in which the organic light emitting layers 1141, 1142, and 1143 are located. The pixel definition layer 1120 may be disposed to surround the first organic light emitting layers 1141 and 1142 of the pixel PX1 of the first type and the second organic light emitting layer 1143 of the pixel PX2 of the second type. The pixel definition layer 1120 may also be located on a z direction side of the first pixel electrode 1131 to overlap at least a partial area of the first pixel electrode 1131, and may divide the first organic light emitting layers 1141 and 1142 of the pixel PX1 of the first type into two or more areas.

In an embodiment of the disclosure, the first pixel electrode 1131 and the second pixel electrode 1132 may be located on a z direction side of the pixel circuit layer 1115.

In an embodiment of the disclosure, the first organic light emitting layers 1141 and 1142 may be located on the z direction side of the first pixel electrode 1131 exposed through the openings of the pixel definition layer 1120. The second organic light emitting layer 1143 may be located on the z direction side of the second pixel electrode 1132 exposed through the openings of the pixel definition layer 1120. The first organic light emitting layers 1141 and 1142 may include the first sub-organic light emitting layer 1141 and the second sub-organic light emitting layer 1142 divided by the pixel definition layer 1120. The first sub-organic light emitting layer 1141 and the second sub-organic light emitting layer 1142, which are spaced apart from each other, may overlap the first pixel electrode 1131 in the z direction.

In an embodiment of the disclosure, the common electrode 1150 may be located on a z direction side of the pixel definition layer 1120, the first organic light emitting layers 1141 and 1142, and the second organic light emitting layer 1143. The common electrode 1150 may be located over the plurality of pixels PX1 and PX2. The first pixel electrode 1131, the first organic light emitting layers 1141 and 1142, and the common electrode 1150 may constitute one organic light emitting diode (OLED), and the second pixel electrode 1132, the second organic light emitting layer 1143, and the common electrode 1150 may constitute one organic light emitting diode (OLED).

In an embodiment of the disclosure, the encapsulation layer 1160 may be located on a z direction side of the common electrode 1150. The encapsulation layer 1160 may cover and seal the organic light emitting diode (OLED). The encapsulation layer 1160 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1160. The first touch pattern layer PL1 may overlap the pixel definition layer 1120 in the z direction. The first touch pattern layer PL1 may not overlap the first organic light emitting layers 1141 and 1142 and the second organic light emitting layer 1143 in the z direction. At least a portion of the first touch pattern layer PL1 may overlap the pixel definition layer 1120 located between the first sub-organic light emitting layer 1141 and the second sub-organic light emitting layer 1142 and the first pixel electrode 1131 in the z direction.

In an embodiment of the disclosure, the insulation layer 1170 may be located on the z direction side of the first touch pattern layer PL1.

In an embodiment of the disclosure, the second touch pattern layer PL2 may be located on the z direction side of the insulation layer 1170. The second touch pattern layer PL2 may overlap the pixel definition layer 1120 in the z direction. The second touch pattern layer PL2 may not overlap the first organic light emitting layers 1141 and 1142 and the second organic light emitting layer 1143 in the z direction. At least a portion of the second touch pattern layer PL2 may overlap the pixel definition layer 1120 located between the first sub-organic light emitting layer 1141 and the second sub-organic light emitting layer 1142 and the first pixel electrode 1131 in the z direction.

In an embodiment of the disclosure, the planarization layer 1175 may be located on the z direction side of the second touch pattern layer PL2.

In an embodiment of the disclosure, the light shielding member 1190 may be located on a z direction side of the planarization layer 1175 to surround peripheries of the first organic light emitting layers 1141 and 1142 of the pixel PX1 of the first type. The light shielding members 1190 may include openings 1191a aligned with the first sub-organic light emitting layer 1141 and the second sub-organic light emitting layer 1142, respectively. The light shielding member 1190 may be disposed to overlap the pixel definition layer 1120 that is adjacent to the first organic light emitting layers 1141 and 1142 in the z direction. At least a portion of the light shielding member 1190 may overlap the pixel definition layer 1120 located between the first sub-organic light emitting layer 1141 and the second sub-organic light emitting layer 1142 in the z direction. Furthermore, at least a portion of the light shielding member 1190 may overlap the first touch pattern layer PL1, the second touch pattern layer PL2, and the first pixel electrode 1131 in the z direction. The electronic device according to an embodiment may include the light shielding member 1190 located at peripheral portions of the first sub-organic light emitting layer 1141 and the second sub-organic light emitting layer 1142, and the first touch pattern layer PL1 and the second touch pattern layer PL2 that overlap the light shielding member 1190 to shield the light that travels at a low angle below the light shielding member 1190.

In an embodiment of the disclosure, the over-coating layer 1195 may be located on the z direction side of the light shielding member 1190.

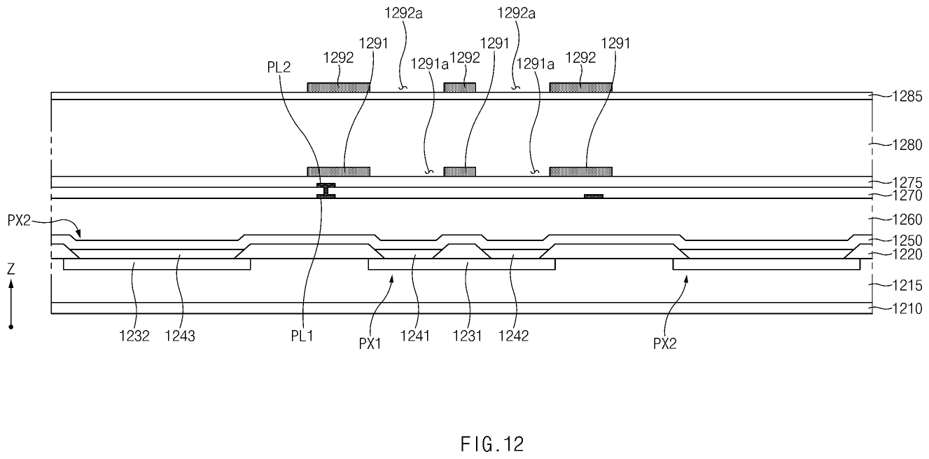

Hereinafter, a cross-sectional structure of the display included in the electronic device according to an embodiment of the disclosure will be described with reference to FIG. 12.

FIG. 12 is a cross-sectional view of an area of a display included in an electronic device according to an embodiment of the disclosure.

Referring to FIG. 12, the display according to an embodiment may include a board 1210, a pixel circuit layer 1215, a pixel definition layer (PDL) 1220, a first pixel electrode 1231, a second pixel electrode 1232, first organic light emitting layers 1241 and 1242, a second organic light emitting layer 1243, a common electrode 1250, an encapsulation layer 1260, the first touch pattern layer PL1, an insulation layer 1270, the second touch pattern layer PL2, a planarization layer 1275, an optical layer 1280, a protection layer 1285, a first light shielding member 1292, and a second light shielding member 1291.

In an embodiment of the disclosure, the pixel circuit layer 1215 may be located on a z direction side of the board 1210. The pixel circuit layer 1215 may include a plurality of wiring lines that deliver a signal for driving the pixels and a plurality of thin film transistors.

In an embodiment of the disclosure, the pixel definition layer 1220 may be located on the z direction side of the pixel circuit layer 1215, and may include openings, in which the organic light emitting layers 1241, 1242, and 1243 are located to divide the light emitting areas. The pixel definition layer 1220 may include openings which expose the first pixel electrode 1231 and the second pixel electrode 1232, and in which the organic light emitting layers 1241, 1242, and 1243 are located. The pixel definition layer 1220 may be disposed to surround the first organic light emitting layers 1241 and 1242 of the pixel PX1 of the first type and the second organic light emitting layer 1243 of the pixel PX2 of the second type. The pixel definition layer 1220 may also be located on a z direction side of the first pixel electrode 1231 to overlap at least a partial area of the first pixel electrode 1231, and may divide the first organic light emitting layers 1241 and 1242 of the pixel PX1 of the first type into two or more areas.

In an embodiment of the disclosure, the first pixel electrode 1231 and the second pixel electrode 1232 may be located on a z direction side of the pixel circuit layer 1215.

In an embodiment of the disclosure, the first organic light emitting layers 1241 and 1242 may be located on the z direction side of the first pixel electrode 1231 exposed through the openings of the pixel definition layer 1220. The second organic light emitting layers 1243 may be located on the z direction side of the second pixel electrode 1232 exposed through the openings of the pixel definition layer 1220. The first organic light emitting layers 1241 and 1242 may include the first sub-organic light emitting layer 1241 and the second sub-organic light emitting layer 1242 divided by the pixel definition layer 1220. The first sub-organic light emitting layer 1241 and the second sub-organic light emitting layer 1242, which are spaced apart from each other, may overlap the first pixel electrode 1231 in the z direction.

In an embodiment of the disclosure, the common electrode 1250 may be located on a z direction side of the pixel definition layer 1220, the first organic light emitting layers 1241 and 1242, and the second organic light emitting layer 1243. The common electrode 1250 may be located over the plurality of pixels PX1 and PX2. The first pixel electrode 1231, the first organic light emitting layers 1241 and 1242, and the common electrode 1250 may constitute one organic light emitting diode (OLED), and the second pixel electrode 1232, the second organic light emitting layer 1243, and the common electrode 1250 may constitute one organic light emitting diode (OLED).

In an embodiment of the disclosure, the encapsulation layer 1260 may be located on a z direction side of the common electrode 1250. The encapsulation layer 1260 may cover and seal the organic light emitting diode (OLED). The encapsulation layer 1260 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1260. The first touch pattern layer PL1 may overlap the pixel definition layer 1220 in the z direction. The first touch pattern layer PL1 may not overlap the first organic light emitting layers 1241 and 1242 and the second organic light emitting layer 1243 in the z direction.

In an embodiment of the disclosure, the insulation layer 1270 may be located on the z direction side of the first touch pattern layer PL1.

In an embodiment of the disclosure, the second touch pattern layer PL2 may be located on the z direction side of the insulation layer 1270. The second touch pattern layer PL2 may overlap the pixel definition layer 1220 in the z direction. The second touch pattern layer PL2 may not overlap the first organic light emitting layers 1241 and 1242 and the second organic light emitting layer 1243 in the z direction.

In an embodiment of the disclosure, the first touch pattern layer PL1 and the second touch pattern layer PL2 may be electrically connected to each other through the connection hole (the via) formed in the insulation layer 1270 located therebetween. A transparent conductive material related to the first touch pattern layer PL1 or the second touch pattern layer PL2 may be filled in the connection hole (the via).

In an embodiment of the disclosure, the planarization layer 1275 may be located on the z direction side of the second touch pattern layer PL2.

In an embodiment of the disclosure, the optical layer 1280 may be located on a z direction side of the planarization layer 1275. For example, the optical layer 1280 may include a material having a refractive index that is larger than a refractive index of an adjacent layer.

In an embodiment of the disclosure, the protection layer 1285 may be located on a z direction side of the optical layer 1280.

In an embodiment of the disclosure, the first light shielding member 1292 may be located on a z direction side of the protection layer 1285 to surround peripheries of the first organic light emitting layers 1241 and 1242 of the pixel PX1 of the first type. The first light shielding members 1292 may include openings 1292a aligned with the first sub-organic light emitting layer 1241 and the second sub-organic light emitting layer 1242, respectively. The first light shielding member 1292 may be disposed to overlap the pixel definition layer 1220 that is adjacent to the first organic light emitting layers 1241 and 1242 in the z direction. At least a portion of the first light shielding member 1292 may overlap the pixel definition layer 1220 located between the first sub-organic light emitting layer 1241 and the second sub-organic light emitting layer 1242 in the z direction. Furthermore, at least a portion of the first light shielding member 1292 may overlap the first touch pattern layer PL1 and the second touch pattern layer PL2 in the z direction.

In an embodiment of the disclosure, the second light shielding member 1291 may be located on the z direction side of the planarization layer 1275. The second light shielding member 1291 may be located between the first light shielding member 1292 and the pixel definition layer 1220. The second light shielding members 1291 may include openings 1291a aligned with the first sub-organic light emitting layer 1241 and the second sub-organic light emitting layer 1242, respectively. The second light shielding member 1291 may overlap the first light shielding member 1292 in the z direction. For example, a periphery of the second light shielding member 1291 may coincide with a periphery of the first light shielding member 1292.

According to an embodiment of the disclosure, although not illustrated in FIG. 12, the first touch pattern layer PL1, the second light shielding member 1291, and the first light shielding member 1292 may overlap each other in a sequence thereof on an upper side of the pixel definition layer 1220 that defines the pixel PX2 of the second type in the z direction.

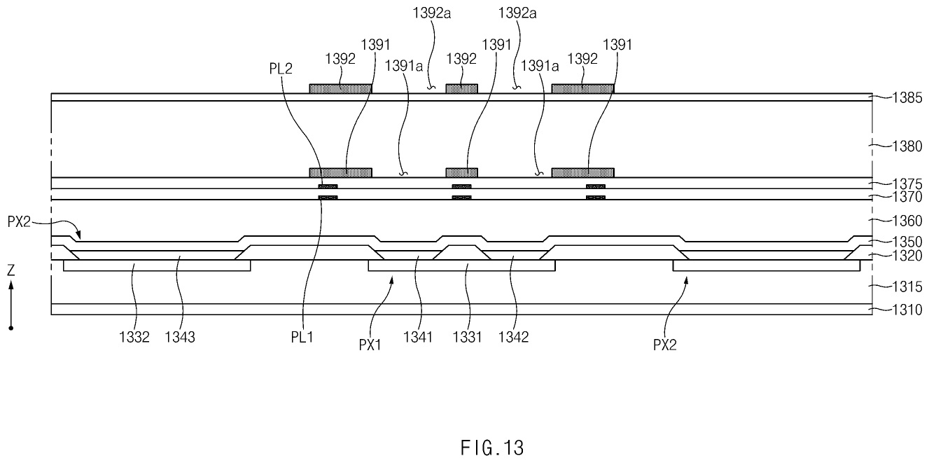

Hereinafter, a cross-sectional structure of the display included in the electronic device according to an embodiment will be described with reference to FIG. 13.

FIG. 13 is a cross-sectional view of an area of a display included in an electronic device according to an embodiment of the disclosure.

Referring to FIG. 13, the display according to an embodiment of the disclosure may include a board 1310, a pixel circuit layer 1315, a pixel definition layer (PDL) 1320, a first pixel electrode 1331, a second pixel electrode 1332, first organic light emitting layers 1341 and 1342, a second organic light emitting layer 1343, a common electrode 1350, an encapsulation layer 1360, the first touch pattern layer PL1, an insulation layer 1370, the second touch pattern layer PL2, a planarization layer 1375, an optical layer 1380, a protection layer 1385, a first light shielding member 1392, and a second light shielding member 1391.

In an embodiment of the disclosure, the pixel circuit layer 1315 may be located on a z direction side of the board 1310. The pixel circuit layer 1315 may include a plurality of wiring lines that deliver a signal for driving the pixels and a plurality of thin film transistors.

In an embodiment of the disclosure, the pixel definition layer 1320 may be located on the z direction side of the pixel circuit layer 1315, and may include openings, in which the organic light emitting layers 1341, 1342, and 1343 are located, to divide the light emitting areas. The pixel definition layer 1320 may include openings which expose the first pixel electrode 1331 and the second pixel electrode 1332, and in which the organic light emitting layers 1341, 1342, and 1343 are located. The pixel definition layer 1320 may be disposed to surround the first organic light emitting layers 1341 and 1342 of the pixel PX1 of the first type and the second organic light emitting layer 1343 of the pixel PX2 of the second type. The pixel definition layer 1320 may also be located on a z direction side of the first pixel electrode 1331 to overlap at least a partial area of the first pixel electrode 1331, and may divide the first organic light emitting layers 1341 and 1342 of the pixel PX1 of the first type into two or more areas.

In an embodiment of the disclosure, the first pixel electrode 1331 and the second pixel electrode 1332 may be located on a z direction side of the pixel circuit layer 1315.

In an embodiment of the disclosure, the first organic light emitting layers 1341 and 1342 may be located on the z direction side of the first pixel electrode 1331 exposed through the openings of the pixel definition layer 1320. The second organic light emitting layers 1343 may be located on the z direction side of the second pixel electrode 1332 exposed through the openings of the pixel definition layer 1320. The first organic light emitting layers 1341 and 1342 may include the first sub-organic light emitting layer 1341 and the second sub-organic light emitting layer 1342 divided by the pixel definition layer 1320. The first sub-organic light emitting layer 1341 and the second sub-organic light emitting layer 1342, which are spaced apart from each other, may overlap the first pixel electrode 1331 in the z direction.

In an embodiment of the disclosure, the common electrode 1350 may be located on a z direction side of the pixel definition layer 1320, the first organic light emitting layers 1341 and 1342, and the second organic light emitting layer 1343. The common electrode 1350 may be located over the plurality of pixels PX1 and PX2. The first pixel electrode 1331, the first organic light emitting layers 1341 and 1342, and the common electrode 1350 may constitute one organic light emitting diode (OLED), and the second pixel electrode 1332, the second organic light emitting layer 1343, and the common electrode 1350 may constitute one organic light emitting diode (OLED).

In an embodiment of the disclosure, the encapsulation layer 1360 may be located on a z direction side of the common electrode 1350. The encapsulation layer 1360 may cover and seal the organic light emitting diode (OLED). The encapsulation layer 1360 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1360. The first touch pattern layer PL1 may overlap the pixel definition layer 1320 in the z direction. The first touch pattern layer PL1 may not overlap the first organic light emitting layers 1341 and 1342 and the second organic light emitting layer 1343 in the z direction. At least a portion of the first touch pattern layer PL1 may overlap the pixel definition layer 1320 located between the first sub-organic light emitting layer 1341 and the second sub-organic light emitting layer 1342 and the first pixel electrode 1331 in the z direction.

In an embodiment of the disclosure, the insulation layer 1370 may be located on the z direction side of the first touch pattern layer PL1.

In an embodiment of the disclosure, the second touch pattern layer PL2 may be located on the z direction side of the insulation layer 1370. The second touch pattern layer PL2 may overlap the pixel definition layer 1320 in the z direction. The second touch pattern layer PL2 may not overlap the first organic light emitting layers 1341 and 1342 and the second organic light emitting layer 1343 in the z direction. At least a portion of the second touch pattern layer PL2 may overlap the pixel definition layer 1320 located between the first sub-organic light emitting layer 1141 and the second sub-organic light emitting layer 1142 and the first pixel electrode 1331 in the z direction.

In an embodiment of the disclosure, the planarization layer 1375 may be located on the z direction side of the second touch pattern layer PL2.

In an embodiment of the disclosure, the optical layer 1380 may be located on a z direction side of the planarization layer 1375. For example, the optical layer 1380 may include a material having a refractive index that is larger than a refractive index of an adjacent layer.

In an embodiment of the disclosure, the protection layer 1385 may be located on a z direction side of the optical layer 1380.

In an embodiment of the disclosure, the first light shielding member 1392 may be located on a z direction side of the protection layer 1385 to surround peripheries of the first organic light emitting layers 1341 and 1342 of the pixel PX1 of the first type. The first light shielding members 1392 may include openings 1392a aligned with the first sub-organic light emitting layer 1341 and the second sub-organic light emitting layer 1342, respectively. The first light shielding member 1392 may be disposed to overlap the pixel definition layer 1320 that is adjacent to the first organic light emitting layers 1341 and 1342 in the z direction. At least a portion of the first light shielding member 1392 may overlap the pixel definition layer 1320 located between the first sub-organic light emitting layer 1341 and the second sub-organic light emitting layer 1342 in the z direction. Furthermore, at least a portion of the first light shielding member 1392 may overlap the first touch pattern layer PL1, the second touch pattern layer PL2, and the first pixel electrode 1331 in the z direction.

In an embodiment of the disclosure, the second light shielding member 1391 may be located between the first light shielding member 1392 and the pixel definition layer 1320. The second light shielding member 1391 may be located on the z direction side of the planarization layer 1375. The second light shielding members 1391 may include openings 1391a aligned with the first sub-organic light emitting layer 1341 and the second sub-organic light emitting layer 1342, respectively. The second light shielding member 1391 may overlap the first light shielding member 1392 in the z direction. For example, a periphery of the second light shielding member 1391 may coincide with a periphery of the first light shielding member 1392.

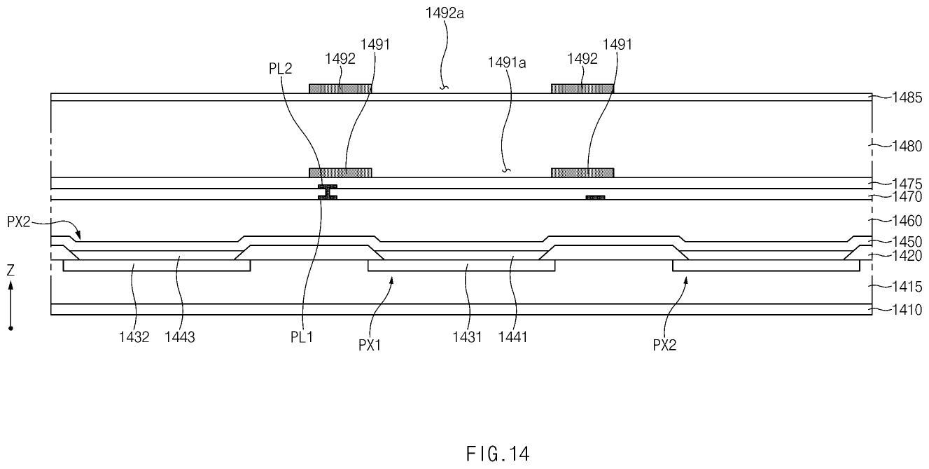

Hereinafter, a cross-sectional structure of the display included in the electronic device according to an embodiment will be described with reference to FIG. 14.

FIG. 14 is a cross-sectional view of an area of a display included in an electronic device according to an embodiment of the disclosure.

Referring to FIG. 14, the display according to an embodiment of the disclosure may include a board 1410, a pixel circuit layer 1415, a pixel definition layer (PDL) 1420, a first pixel electrode 1431, a second pixel electrode 1432, a first organic light emitting layer 1441, a second organic light emitting layer 1443, a common electrode 1450, an encapsulation layer 1460, the first touch pattern layer PL1, an insulation layer 1470, the second touch pattern layer PL2, a planarization layer 1475, an optical layer 1480, a protection layer 1485, a first light shielding member 1492, and a second light shielding member 1491.

In an embodiment of the disclosure, the pixel circuit layer 1415 may be located on a z direction side of the board 1410. The pixel circuit layer 1415 may include a plurality of wiring lines that deliver a signal for driving the pixels and a plurality of thin film transistors.

In an embodiment of the disclosure, the pixel definition layer 1420 may be located on the z direction side of the pixel circuit layer 1415, and may include openings, in which the organic light emitting layers 1441 and 1443 are located, to divide the light emitting areas. The pixel definition layer 1420 may include openings which expose the first pixel electrode 1431 and the second pixel electrode 1432, and in which the organic light emitting layers 1441 and 1443. The pixel definition layer 1420 may be disposed to surround the first organic light emitting layer 1441 of the pixel PX1 of the first type and the second organic light emitting layer 1043 of the pixel PX2 of the second type.

In an embodiment of the disclosure, the first pixel electrode 1431 and the second pixel electrode 1432 may be located on a z direction side of the pixel circuit layer 1415.

In an embodiment of the disclosure, the first organic light emitting layer 1441 may be located on the z direction side of the first pixel electrode 1431 exposed through the openings of the pixel definition layer 1420. The second organic light emitting layers 1443 may be located on the z direction side of the second pixel electrode 1432 exposed through the openings of the pixel definition layer 1420.

In an embodiment of the disclosure, the common electrode 1450 may be located on a z direction side of the pixel definition layer 1420, the first organic light emitting layer 1441, and the second organic light emitting layer 1043. The common electrode 1450 may be located over the plurality of pixels PX1 and PX2. The first pixel electrode 1431, the first organic light emitting layer 1441, and the common electrode 1450 may constitute one organic light emitting diode (OLED), and the second pixel electrode 1432, the second organic light emitting layer 1443, and the common electrode 1050 may constitute one organic light emitting diode (OLED).

In an embodiment of the disclosure, the encapsulation layer 1460 may be located on a z direction side of the common electrode 1450. The encapsulation layer 1460 may cover and seal the organic light emitting diode (OLED). The encapsulation layer 1460 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1460. The first touch pattern layer PL1 may overlap the pixel definition layer 1420 in the z direction. The first touch pattern layer PL1 may not overlap the first organic light emitting layers 1441 and the second organic light emitting layer 1443 in the z direction.

In an embodiment of the disclosure, the insulation layer 1470 may be located on the z direction side of the first touch pattern layer PL1.

In an embodiment of the disclosure, the second touch pattern layer PL2 may be located on the z direction side of the insulation layer 1470. The second touch pattern layer PL2 may overlap the pixel definition layer 1420 in the z direction. The second touch pattern layer PL2 may not overlap the first organic light emitting layers 1441 and the second organic light emitting layer 1443 in the z direction.

In an embodiment of the disclosure, the first touch pattern layer PL1 and the second touch pattern layer PL2 may be electrically connected to each other through the connection hole (the via) formed in the insulation layer 1470 located therebetween. A transparent conductive material related to the first touch pattern layer PL1 or the second touch pattern layer PL2 may be filled in the connection hole (the via).

In an embodiment of the disclosure, the planarization layer 1475 may be located on the z direction side of the second touch pattern layer PL2.

In an embodiment of the disclosure, the optical layer 1480 may be located on a z direction side of the planarization layer 1475. For example, the optical layer 1480 may include a material having a refractive index that is larger than a refractive index of an adjacent layer.

In an embodiment of the disclosure, the protection layer 1485 may be located on a z direction side of the optical layer 1480.

In an embodiment of the disclosure, the first light shielding member 1492 may be located on a z direction side of the protection layer 1485 to surround peripheries of the first organic light emitting layer 1441 of the pixel PX1 of the first type. The first light shielding member 1492 may include an opening 1492a aligned with the first organic light emitting layer 1441. The first light shielding member 1492 may be disposed to overlap the pixel definition layer 1420 that is adjacent to the first organic light emitting layer 1441 in the z direction.

In an embodiment of the disclosure, the second light shielding member 1491 may be located between the first light shielding member 1492 and the pixel definition layer 1420. The second light shielding member 1491 may be located on the z direction side of the planarization layer 1475. The second light shielding member 1491 may include an opening 1491a aligned with the first organic light emitting layer 1441. The second light shielding member 1491 may overlap the first light shielding member 1392 in the z direction. For example, a periphery of the second light shielding member 1491 may coincide with a periphery of the first light shielding member 1492.

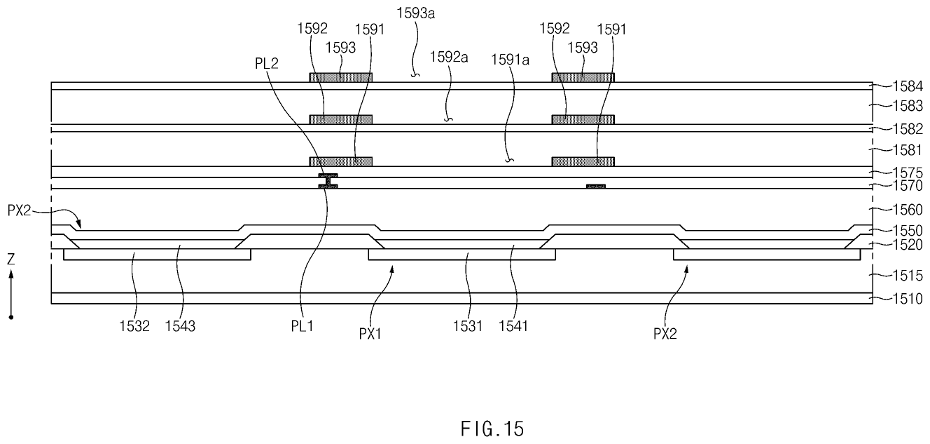

Hereinafter, a cross-sectional structure of the display included in the electronic device according to an embodiment will be described with reference to FIG. 15.

FIG. 15 is a cross-sectional view of an area of a display included in an electronic device according to an embodiment of the disclosure.

Referring to FIG. 15, the display according to an embodiment of the disclosure may include a board 1510, a pixel circuit layer 1515, a pixel definition layer (PDL) 1520, a first pixel electrode 1531, a second pixel electrode 1532, a first organic light emitting layer 1541, a second organic light emitting layer 1543, a common electrode 1550, an encapsulation layer 1560, the first touch pattern layer PL1, an insulation layer 1570, the second touch pattern layer PL2, a planarization layer 1575, a first optical layer 1581, a first protection layer 1582, a second optical layer 1583, a second protection layer 1584, a first light shielding member 1593, a second light shielding member 1592, and a third light shielding member 1591.

In an embodiment of the disclosure, the pixel circuit layer 1515 may be located on a z direction side of the board 1510. The pixel circuit layer 1515 may include a plurality of wiring lines that deliver a signal for driving the pixels and a plurality of thin film transistors.

In an embodiment of the disclosure, the pixel definition layer 1520 may be located on the z direction side of the pixel circuit layer 1515, and may include openings, in which the organic light emitting layers 1541 and 1543 are located, to divide the light emitting areas. The pixel definition layer 1520 may include openings which expose the first pixel electrode 1531 and the second pixel electrode 1532, and in which the organic light emitting layers 1541 and 1543 are located. The pixel definition layer 1520 may be disposed to surround the first organic light emitting layer 1541 of the pixel PX1 of the first type and the second organic light emitting layer 1543 of the pixel PX2 of the second type.

In an embodiment of the disclosure, the first pixel electrode 1531 and the second pixel electrode 1532 may be located on a z direction side of the pixel circuit layer 1515.

In an embodiment of the disclosure, the first organic light emitting layer 1541 may be located on the z direction side of the first pixel electrode 1531 exposed through the openings of the pixel definition layer 1520. The second organic light emitting layers 1543 may be located on the z direction side of the second pixel electrode 1532 exposed through the openings of the pixel definition layer 1520.

In an embodiment of the disclosure, the common electrode 1550 may be located on a z direction side of the pixel definition layer 1520, the first organic light emitting layer 1541, and the second organic light emitting layer 1543. The common electrode 1550 may be located over the plurality of pixels PX1 and PX2. The first pixel electrode 1531, the first organic light emitting layer 1541, and the common electrode 1550 may constitute one organic light emitting diode (OLED), and the second pixel electrode 1532, the second organic light emitting layer 1543, and the common electrode 1550 may constitute one organic light emitting diode (OLED).

In an embodiment of the disclosure, the encapsulation layer 1560 may be located on a z direction side of the common electrode 1550. The encapsulation layer 1560 may cover and seal the organic light emitting diode (OLED). The encapsulation layer 1560 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1560. The first touch pattern layer PL1 may overlap the pixel definition layer 1520 in the z direction. The first touch pattern layer PL1 may not overlap the first organic light emitting layer 1541 and the second organic light emitting layer 1543 in the z direction.

In an embodiment of the disclosure, the insulation layer 1570 may be located on the z direction side of the first touch pattern layer PL1.

In an embodiment of the disclosure, the second touch pattern layer PL2 may be located on the z direction side of the insulation layer 1570. The second touch pattern layer PL2 may overlap the pixel definition layer 1520 in the z direction. The second touch pattern layer PL2 may not overlap the first organic light emitting layer 1541 and the second organic light emitting layer 1543 in the z direction.

In an embodiment of the disclosure, the first touch pattern layer PL1 and the second touch pattern layer PL2 may be electrically connected to each other through the connection hole (the via) formed in the insulation layer 1570 located therebetween. A transparent conductive material related to the first touch pattern layer PL1 or the second touch pattern layer PL2 may be filled in the connection hole (the via).

In an embodiment of the disclosure, the planarization layer 1575 may be located on the z direction side of the second touch pattern layer PL2.

In an embodiment of the disclosure, the first optical layer 1581 may be located on the z direction side of the planarization layer 1575. For example, the first optical layer 1581 may include a material having a refractive index that is larger than a refractive index of an adjacent layer.

In an embodiment of the disclosure, the first protection layer 1582 may be located on the z direction side of the first optical layer 1581.

In an embodiment of the disclosure, the second optical layer 1583 may be located on the z direction side of the first protection layer 1582.

In an embodiment of the disclosure, the second protection layer 1584 may be located on the z direction side of the second optical layer 1583.

In an embodiment of the disclosure, the first light shielding member 1593 may be located on a z direction side of the second protection layer 1584 to surround peripheries of the first organic light emitting layer 1541 of the pixel PX1 of the first type. The first light shielding member 1593 may include an opening 1593a aligned with the first organic light emitting layer 1541. The first light shielding member 1593 may be disposed to overlap the pixel definition layer 1520 that is adjacent to the first organic light emitting layer 1541 in the z direction.

In an embodiment of the disclosure, the second light shielding member 1592 may be located between the first light shielding member 1593 and the pixel definition layer 1520. The second light shielding member 1592 may be located on the z direction side of the first protection layer 1582. The second light shielding member 1592 may include an opening 1592a aligned with the first organic light emitting layer 1541. The second light shielding member 1592 may overlap the first light shielding member 1593 in the z direction. For example, a periphery of the second light shielding member 1592 may coincide with a periphery of the first light shielding member 1593.

In an embodiment of the disclosure, the third light shielding member 1591 may be located between the first light shielding member 1593 and the pixel definition layer 1520. The third light shielding member 1591 may be located on the z direction side of the planarization layer 1575. The third light shielding member 1591 may include an opening 1591a aligned with the first organic light emitting layer 1541. The third light shielding member 1591 may overlap the first light shielding member 1593 and the second light shielding member 1592 in the z direction. For example, a periphery of the third light shielding member 1591 may coincide with peripheries of the first light shielding member 1593 and/or the second light shielding member 1592.

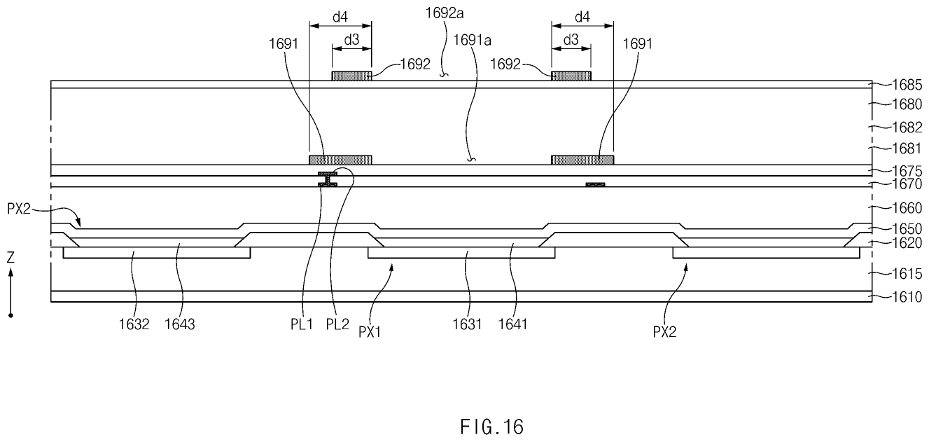

In an embodiment of the disclosure, the first light shielding member 1593, the second light shielding member 1592, and the third light shielding member 1591 may have different widths such that the peripheries thereof do not coincide with each other. For example, the periphery of the first light shielding member 1593, the periphery of the second light shielding member 1592, and the third light shielding member 1591 may not coincide with each other. For example, at least portions of the first light shielding member 1593, the second light shielding member 1592, and the third light shielding member 1591 may overlap each other in the z direction such that widths (e.g., a width d3 of FIG. 16, and a width d4 of FIG. 16) of the light shielding members are different. In an embodiment of the disclosure, widths of the first light shielding member 1593, the second light shielding member 1592, and the third light shielding member 1591 may become gradually larger in a sequence thereof.

Hereinafter, a cross-sectional structure of the display included in the electronic device according to an embodiment will be described with reference to FIG. 16.

FIG. 16 is a cross-sectional view of an area of a display included in an electronic device according to an embodiment of the disclosure.

Referring to FIG. 16, the display according to an embodiment of the disclosure may include a board 1610, a pixel circuit layer 1615, a pixel definition layer (PDL) 1620, a first pixel electrode 1631, a second pixel electrode 1632, a first organic light emitting layer 1641, a second organic light emitting layer 1643, a common electrode 1650, an encapsulation layer 1660, the first touch pattern layer PL1, an insulation layer 1670, the second touch pattern layer PL2, a planarization layer 1675, an optical layer 1680, a first optical layer 1681, a first protection layer 1682, a protection layer 1685, a first light shielding member 1692, and a second light shielding member 1691.

In an embodiment of the disclosure, the pixel circuit layer 1615 may be located on a z direction side of the board 1610. The pixel circuit layer 1615 may include a plurality of wiring lines that deliver a signal for driving the pixels and a plurality of thin film transistors.

In an embodiment of the disclosure, the pixel definition layer 1620 may be located on the z direction side of the pixel circuit layer 1615, and may include openings, in which the organic light emitting layers 1641 and 1643 are located, to divide the light emitting areas. The pixel definition layer 1620 may include openings which expose the first pixel electrode 1631 and the second pixel electrode 1632, and in which the organic light emitting layers 1641 and 1643 are located. The pixel definition layer 1620 may be disposed to surround the first organic light emitting layer 1641 of the pixel PX1 of the first type and the second organic light emitting layer 1643 of the pixel PX2 of the second type.

In an embodiment of the disclosure, the first pixel electrode 1631 and the second pixel electrode 1632 may be located on a z direction side of the pixel circuit layer 1615.

In an embodiment of the disclosure, the first organic light emitting layer 1641 may be located on the z direction side of the first pixel electrode 1631 exposed through the openings of the pixel definition layer 1620. The second organic light emitting layer 1643 may be located on the z direction side of the second pixel electrode 1632 exposed through the openings of the pixel definition layer 1620.

In an embodiment of the disclosure, the common electrode 1650 may be located on a z direction side of the pixel definition layer 1620, the first organic light emitting layer 1641, and the second organic light emitting layer 1643. The common electrode 1650 may be located over the plurality of pixels PX1 and PX2. The first pixel electrode 1631, the first organic light emitting layer 1641, and the common electrode 1650 may constitute one organic light emitting diode (OLED), and the second pixel electrode 1632, the second organic light emitting layer 1643, and the common electrode 1650 may constitute one organic light emitting diode (OLED).

In an embodiment of the disclosure, the encapsulation layer 1660 may be located on a z direction side of the common electrode 1650. The encapsulation layer 1660 may cover and seal the organic light emitting diode (OLED). The encapsulation layer 1660 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1360. The first touch pattern layer PL1 may overlap the pixel definition layer 1620 in the z direction. The first touch pattern layer PL1 may not overlap the first organic light emitting layer 1641 and the second organic light emitting layer 1643 in the z direction.

In an embodiment of the disclosure, the insulation layer 1670 may be located on the z direction side of the first touch pattern layer PL1.

In an embodiment of the disclosure, the second touch pattern layer PL2 may be located on the z direction side of the insulation layer 1670. The second touch pattern layer PL2 may overlap the pixel definition layer 1620 in the z direction. The second touch pattern layer PL2 may not overlap the first organic light emitting layer 1641 and the second organic light emitting layer 1643 in the z direction.

In an embodiment of the disclosure, the first touch pattern layer PL1 and the second touch pattern layer PL2 may be electrically connected to each other through the connection hole (the via) formed in the insulation layer 1670 located therebetween. A transparent conductive material related to the first touch pattern layer PL1 or the second touch pattern layer PL2 may be filled in the connection hole (the via).

In an embodiment of the disclosure, the planarization layer 1675 may be located on the z direction side of the second touch pattern layer PL2.

In an embodiment of the disclosure, the optical layer 1680 may be located on a z direction side of the planarization layer 1675. For example, the optical layer 1680 may include a material having a refractive index that is larger than a refractive index of an adjacent layer.

In an embodiment of the disclosure, the protection layer 1685 may be located on a z direction side of the optical layer 1680.

In an embodiment of the disclosure, the first light shielding member 1692 may be located on a z direction side of the protection layer 1685 to surround peripheries of the first organic light emitting layer 1641 of the pixel PX1 of the first type. The first light shielding member 1692 may include an opening 1692a aligned with the first organic light emitting layer 1641. The first light shielding member 1692 may be disposed to overlap the pixel definition layer 1620 that is adjacent to the first organic light emitting layer 1641 in the z direction.

In an embodiment of the disclosure, the second light shielding member 1691 may be located between the first light shielding member 1692 and the pixel definition layer 1620. The second light shielding member 1691 may be located on the z direction side of the planarization layer 1675. The second light shielding member 1691 may include an opening 1691a aligned with the first organic light emitting layer 1641. The second light shielding member 1691 may overlap the first light shielding member 1692 in the z direction. The width d3 of the first light shielding member 1692 may be smaller than a width d4 of the second light shielding member 1691. A periphery of the opening 1691a of the second light shielding member 1691 may coincide with the periphery of the opening 1692a of the first light shielding member 1692.

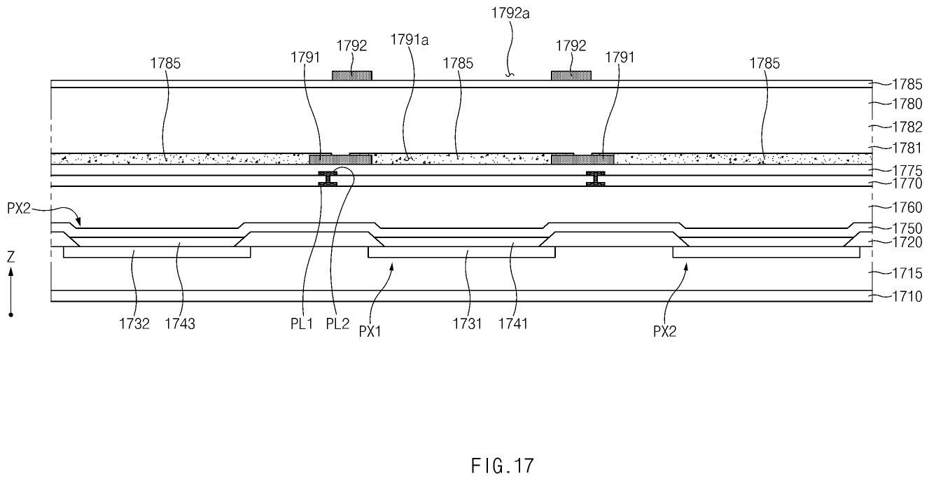

Hereinafter, a cross-sectional structure of the display included in the electronic device according to an embodiment will be described with reference to FIG. 17.

FIG. 17 is a cross-sectional view of an area of a display included in an electronic device according to an embodiment of the disclosure.

Referring to FIG. 17, the display according to an embodiment of the disclosure may include a board 1710, a pixel circuit layer 1715, a pixel definition layer (PDL) 1720, a first pixel electrode 1731, a second pixel electrode 1732, a first organic light emitting layer 1741, a second organic light emitting layer 1743, a common electrode 1750, an encapsulation layer 1760, the first touch pattern layer PL1, an insulation layer 1770, the second pattern layer PL2, a planarization layer 1775, a color filter 1785, an optical layer 1780, a first optical layer 1781, a first protection layer 1782, a protection layer 1785, a first light shielding member 1792, a second light shielding member 1791.

In an embodiment of the disclosure, the pixel circuit layer 1715 may be located on a z direction side of the board 1710. The pixel circuit layer 1715 may include a plurality of wiring lines that deliver a signal for driving the pixels and a plurality of thin film transistors.

In an embodiment of the disclosure, the pixel definition layer 1720 may be located on the z direction side of the pixel circuit layer 1715, and may include openings, in which the organic light emitting layers 1741 and 1743 are located, to divide the light emitting areas. The pixel definition layer 1720 may include openings which expose the first pixel electrode 1731 and the second pixel electrode 1732, and in which the organic light emitting layers 1741 and 1743 are located. The pixel definition layer 1720 may be disposed to surround the first organic light emitting layer 1741 of the pixel PX1 of the first type and the second organic light emitting layer 1743 of the pixel PX2 of the second type.

In an embodiment of the disclosure, the first pixel electrode 1731 and the second pixel electrode 1732 may be located on a z direction side of the pixel circuit layer 1715.

In an embodiment of the disclosure, the first organic light emitting layer 1741 may be located on the z direction side of the first pixel electrode 1731 exposed through the openings of the pixel definition layer 1720. The second organic light emitting layer 1743 may be located on the z direction side of the second pixel electrode 1732 exposed through the openings of the pixel definition layer 1720.

In an embodiment of the disclosure, the common electrode 1750 may be located on a z direction side of the pixel definition layer 1720, the first organic light emitting layer 1741, and the second organic light emitting layer 1743. The common electrode 1750 may be located over the plurality of pixels PX1 and PX2. The first pixel electrode 1731, the first organic light emitting layer 1741, and the common electrode 1750 may constitute one organic light emitting diode (OLED), and the second pixel electrode 1732, the second organic light emitting layer 1743, and the common electrode 1750 may constitute one organic light emitting diode (OLED).

In an embodiment of the disclosure, the encapsulation layer 1760 may be located on a z direction side of the common electrode 1750. The encapsulation layer 1760 may cover and seal the organic light emitting diode (OLED). The encapsulation layer 1760 may include a plurality of layers, and may include a triple layer, in which an inorganic film, an organic film, and an inorganic film are sequentially laminated.

In an embodiment of the disclosure, the first touch pattern layer PL1 may be located on the z direction side of the encapsulation layer 1760. The first touch pattern layer PL1 may overlap the pixel definition layer 1720 in the z direction. The first touch pattern layer PL1 may not overlap the first organic light emitting layer 1741 and the second organic light emitting layer 1743 in the z direction.

In an embodiment of the disclosure, the insulation layer 1770 may be located on the z direction side of the first touch pattern layer PL1.

In an embodiment of the disclosure, the second touch pattern layer PL2 may be located on the z direction side of the insulation layer 1770. The second touch pattern layer PL2 may overlap the pixel definition layer 1720 in the z direction. The second touch pattern layer PL2 may not overlap the first organic light emitting layer 1741 and the second organic light emitting layer 1743 in the z direction.

In an embodiment of the disclosure, the first touch pattern layer PL1 and the second touch pattern layer PL2 may be electrically connected to each other through the connection hole (the via) formed in the insulation layer 1770 located therebetween. A transparent conductive material related to the first touch pattern layer PL1 or the second touch pattern layer PL2 may be filled in the connection hole (the via).

In an embodiment of the disclosure, the planarization layer 1775 may be located on the z direction side of the second touch pattern layer PL2.

In an embodiment of the disclosure, the color filter 1785 may be located on a z direction side of the planarization layer 1775. The color filter 1785 may include a red color filter that transmits light of a wavelength of a red area, a green color filter that transmits light of a wavelength of a green area, and a blue color filter that transmits light of a wavelength of a blue area. The color filter 1785 may be aligned with the first organic light emitting layer 1741 and the second organic light emitting layer 1743 in the z direction. At least a portion of the color filter 1785 may be located in an opening 1791a of the second light shielding member 1791.

In an embodiment of the disclosure, the optical layer 1780 may be located on a z direction side of the color filter 1785. For example, the optical layer 1780 may include a material having a refractive index that is larger than a refractive index of an adjacent layer.

In an embodiment of the disclosure, the protection layer 1785 may be located on a z direction side of the optical layer 1780.

In an embodiment of the disclosure, the first light shielding member 1792 may be located on a z direction side of the protection layer 1785 to surround peripheries of the first organic light emitting layer 1741 of the pixel PX1 of the first type. The first light shielding member 1792 may include an opening 1792a aligned with the first organic light emitting layer 1741. The first light shielding member 1792 may be disposed to overlap the pixel definition layer 1720 that is adjacent to the first organic light emitting layers 1741 in the z direction.

In an embodiment of the disclosure, the second shielding layer 1791 may be located on the z direction side of the planarization layer 1775. The second light shielding member 1791 may include an opening 1791a aligned with the first organic light emitting layer 1741. The second light shielding member 1791 may overlap the first light shielding member 1792 in the z direction. The width of the first light shielding member 1792 may be smaller than the width of the second light shielding member 1791. A periphery of the opening 1791a of the second light shielding member 1791 may coincide with the periphery of the opening 1792a of the first light shielding member 1792.

An electronic device 101 according to an embodiment of the disclosure may include a board 1010, a plurality of pixels including a first pixel PX1 disposed on the board, and including a first organic light emitting layer 1041 and 1042 including a first sub-organic light emitting layer 1041 and a second sub-organic light emitting layer 1042, which are spaced apart from each other, and a second pixel PX2 including a second organic light emitting layer 1043, a pixel definition layer 1020 located between the first sub-organic light emitting layer and the second sub-organic light emitting layer, a first light shielding member 1090, 1292, and 1392 located on the pixel definition layer to overlap the pixel definition layer between the first sub-organic light emitting layer and the second sub-organic light emitting layer in a first direction, and an opaque member PL1, PL2, 1291, and 1392 overlapping the first light shielding member in the first direction, and located between at least a portion of the pixel definition layer located between the first sub-organic light emitting layer and the second sub-organic light emitting layer, and the first light shielding member.

According to various embodiments of the disclosure, the electronic device may further include a first touch pattern layer PL1 including a plurality of unit pattern lines that cross each other, an insulation layer 1270 located on the first touch pattern layer, and a second touch pattern layer PL2 located on the insulation layer, and including a plurality of unit pattern lines that cross each other, and the second touch pattern layer may include the opaque member.

According to various embodiments of the disclosure, at least some of the plurality of unit pattern lines of the second touch pattern layer may overlap the first light shielding member in the first direction.

According to various embodiments of the disclosure, at least some of the plurality of unit pattern lines of the first touch pattern layer may overlap at least some of the plurality of unit pattern lines of the first light shielding member and the second touch pattern layer in the first direction.

According to various embodiments of the disclosure, the plurality of unit pattern lines of the first touch pattern layer and the plurality of unit pattern lines of the second touch pattern layer may not overlap the first organic light emitting layer and the second organic light emitting layer in the first direction.

According to various embodiments of the disclosure, a distance between two of the plurality of unit pattern lines of the second touch pattern layer, which are adjacent to the first sub-organic light emitting layer of the first pixel, may be smaller than a distance between two thereof, which are adjacent to the second organic light emitting layer of the second pixel.

According to various embodiments of the disclosure, the electronic device may further include a first touch electrode that delivers a first touch signal, and including first touch cells, and first connection members connecting the first touch cells that are adjacent to each other along one direction, and a second touch electrode that delivers a second touch signal, and including second touch cells, and second connection members connecting the second touch cells that are adjacent to each other along one direction.

According to various embodiments of the disclosure, the first touch pattern layer may include the first touch cells, the first connection members, and the second touch cells, and the second touch pattern layer may include the second connection members.

According to various embodiments of the disclosure, the second touch pattern layer may further include a light shielding pattern spaced apart from the second connection members and that floats.

According to various embodiments of the disclosure, the electronic device may further include a second light shielding member overlapping the first light shielding member, and at least some of the plurality of unit pattern lines of the second touch pattern layer in the first direction.

According to various embodiments of the disclosure, the electronic device may further include a third light shielding member overlapping the first light shielding member and the opaque member in the first direction.

According to various embodiments of the disclosure, a width of the first light shielding member is smaller than a width of the opaque member.

According to various embodiments of the disclosure, the electronic device may further include a color filter 1785, the opaque member may include an opening aligned with the first organic light emitting layer in the first direction, and at least a portion of the color filter may be located in the opening of the opaque member.

An electronic device 101 according to an embodiment of the disclosure may include a display 210, and the display may include a first pixel PX1 including at least two light emitting areas R11, R12, R13, R14, G11, G12, G13, G14, G15, G16, G17, G18, B11, B12, B13, and B14 that are driven based on the same data voltage and the same gate signal and are spaced apart from each other, a first light shielding member including a plurality of openings located on the first pixel to surround the light emitting areas of the first pixel and aligned with the light emitting areas of the first pixel, and an opaque member overlapping the first light shielding member in a first direction.

According to various embodiments of the disclosure, the opaque member may deliver a touch signal.

According to various embodiments of the disclosure, the display may further include a touch pattern layer that delivers a touch signal, and the opaque member may be located on the same layer as the touch pattern layer.

According to various embodiments of the disclosure, the display may further include an optical layer located between the opaque member and the first light shielding member.

According to various embodiments of the disclosure, the display may further include a second light shielding member overlapping the first light shielding member in the first direction.

According to various embodiments of the disclosure, a width of the first light shielding member may be smaller than a width of the opaque member.

According to various embodiments of the disclosure, a periphery of the first light shielding member may coincide with a periphery of the opaque member.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a board;
a plurality of pixels including a first pixel disposed on the board, and including a first organic light emitting layer including a first sub-organic light emitting layer and a second sub-organic light emitting layer, which are spaced apart from each other, and a second pixel including a second organic light emitting layer;
a pixel definition layer located between the first sub-organic light emitting layer and the second sub-organic light emitting layer;
a first light shielding member located on the pixel definition layer to overlap the pixel definition layer between the first sub-organic light emitting layer and the second sub-organic light emitting layer in a first direction; and
an opaque member overlapping the first light shielding member in the first direction, and located between at least a portion of the pixel definition layer located between the first sub-organic light emitting layer and the second sub-organic light emitting layer, and the first light shielding member.

2. The electronic device of claim 1, further comprising:
a first touch pattern layer including a plurality of unit pattern lines that cross each other;
an insulation layer located on the first touch pattern layer; and
a second touch pattern layer located on the insulation layer, and including a plurality of unit pattern lines that cross each other,
wherein the second touch pattern layer includes the opaque member.

3. The electronic device of claim 2, wherein at least some of the plurality of unit pattern lines of the second touch pattern layer overlap the first light shielding member in the first direction.

4. The electronic device of claim 3, wherein at least some of the plurality of unit pattern lines of the first touch pattern layer overlap at least some of the plurality of unit pattern lines of the first light shielding member and the second touch pattern layer in the first direction.

5. The electronic device of claim 4, wherein the plurality of unit pattern lines of the first touch pattern layer and the plurality of unit pattern lines of the second touch pattern layer do not overlap the first organic light emitting layer and the second organic light emitting layer in the first direction.

6. The electronic device of claim 3, wherein a distance between two of the plurality of unit pattern lines of the second touch pattern layer, which are adjacent to the first sub-organic light emitting layer of the first pixel, is smaller than a distance between two thereof, which are adjacent to the second organic light emitting layer of the second pixel.

7. The electronic device of claim 3, further comprising:
a first touch electrode configured to deliver a first touch signal, and including first touch cells, and first connection members connecting the first touch cells that are adjacent to each other along one direction; and
a second touch electrode configured to deliver a second touch signal, and including second touch cells, and second connection members connecting the second touch cells that are adjacent to each other along one direction.

8. The electronic device of claim 7,
wherein the first touch pattern layer includes the first touch cells, the first connection members, and the second touch cells, and
wherein the second touch pattern layer includes the second connection members.

9. The electronic device of claim 8, wherein the second touch pattern layer further includes a light shielding pattern spaced apart from the second connection members and that floats.

10. The electronic device of claim 9, further comprising:
a second light shielding member overlapping the first light shielding member, and at least some of the plurality of unit pattern lines of the second touch pattern layer in the first direction.

11. The electronic device of claim 1, further comprising:
a third light shielding member overlapping the first light shielding member and the opaque member in the first direction.

12. The electronic device of claim 1, wherein a width of the first light shielding member is smaller than a width of the opaque member.

13. The electronic device of claim 12, further comprising:
a color filter,
wherein the opaque member includes an opening aligned with the first organic light emitting layer in the first direction, and
wherein at least a portion of the color filter is located in the opening of the opaque member.

14. An electronic device comprising:
a display, and
wherein the display includes:
a first pixel including at least two light emitting areas that are driven based on the same data voltage and the same gate signal and are spaced apart from each other,
a first light shielding member including a plurality of openings located on the first pixel to surround the light emitting areas of the first pixel and aligned with the light emitting areas of the first pixel, and
an opaque member overlapping the first light shielding member in a first direction.

15. The electronic device of claim 14, wherein the opaque member delivers a touch signal.

16. The electronic device of claim 14,
wherein the display further includes a touch pattern layer configured to deliver a touch signal, and
wherein the opaque member is located on the same layer as the touch pattern layer.

17. The electronic device of claim 14, wherein the display further includes an optical layer located between the opaque member and the first light shielding member.

18. The electronic device of claim 14, wherein the display further includes a second light shielding member overlapping the first light shielding member in the first direction.

19. The electronic device of claim 14, wherein a width of the first light shielding member is smaller than a width of the opaque member.

20. The electronic device of claim 14, wherein a periphery of the first light shielding member coincides with a periphery of the opaque member.
